(19) United States
(12) Patent Application Publication
(10) Pub. No.: US 2025/0306465 A1
(43) Pub. Date: Oct. 2, 2025

(54) PHOTOSENSITIVE MULTILAYER RESIN FILM, PRINTED WIRING BOARD, SEMICONDUCTOR PACKAGE, AND METHOD FOR PRODUCING PRINTED WIRING BOARD

(71) Applicant: Resonac Corporation, Tokyo (JP)

(72) Inventors: Yuko KONNO, Tokyo (JP); Tomohiro AYUGASE, Tokyo (JP); Ryo YUKIOKA, Tokyo (JP)

(21) Appl. No.: 18/849,844

(22) PCT Filed: Mar. 30, 2023
(86) PCT No.: PCT/JP2023/013040

§ 371 Date: Sep. 23, 2024

(30) Foreign Application Priority Data
Mar. 31, 2022 (JP) 2022-060833

(51) Int. Cl. G03F 7/095; G03F 7/004; G03F 7/028; G03F 7/032; G03F 7/037; G03F 7/075; G03F 7/09; H01L 23/498

(52) U.S. Cl. CPC G03F 7/0957; G03F 7/0046; G03F 7/028; G03F 7/032; G03F 7/037; G03F 7/0755; G03F 7/094; H01L 23/49894

(57) ABSTRACT

The present invention relates to a photosensitive multilayer resin film including: a first resin composition layer; and a second resin composition layer. The first resin composition layer and the second resin composition layer each contain a compound (A) having an ethylenically unsaturated group, a thermosetting resin (B), a photopolymerization initiator (C), and an inorganic filler (D). The second resin composition layer further contains a fluorine-containing resin (E). A fluorine atom concentration in the first resin composition layer is lower than a fluorine atom concentration in the second resin composition layer.

### TECHNICAL FIELD

The present disclosure relates to a photosensitive multilayer resin film, a printed wiring board, a semiconductor package, and a method for producing a printed wiring board.

### BACKGROUND ART

In recent years, miniaturization and high performance of electronic devices have been advanced, and printed wiring boards have been increased in density due to an increase in the number of circuit layers and miniaturization of wiring. Particularly, an increase in density of semiconductor packages such as a ball grid array (BGA) and a chip size package (CSP) on which semiconductor chips are mounted is significant. Therefore, for the printed wiring board, in addition to the miniaturization of wiring, thinning of an interlayer insulating layer and a reduction in diameter of an interlayer connection via are required.

As a method for producing a printed wiring board which is adopted in the related art, a method for producing a multilayer printed wiring board by a build-up method in which an interlayer insulating layer and a conductor circuit layer are sequentially laminated and formed (for example, refer to PTL 1) is exemplified. In a multilayer printed wiring board, a semi-additive process in which a circuit is formed by plating has been mainly used along with miniaturization of circuit. In the semi-additive process in the related art, a thermosetting resin film has been used to form an interlayer insulating layer.

A laser process is mainly used as a method for forming a via in an interlayer insulating layer formed by a thermosetting resin film. However, limits are being reached in reducing a diameter of a via by the laser process. In formation of a via by the laser process, it is necessary to form via holes one by one. Therefore, when it is necessary to form a large number of vias in order to increase a density, it takes a long time to form the vias, resulting in high production costs and low production efficiency.

Under such circumstances, a method of collectively forming a plurality of small-diameter vias by a photolithography method using a photosensitive resin film has been proposed (for example, refer to PTL 2).

### CITATION LIST

### Patent Literature

PTL 1: JPH 7-304931 A

PTL 2: JP 2017-116652 A

### SUMMARY OF INVENTION

### Technical Problem

In recent years, an increase in speed and an increase in capacity of a signal to be used in electronic devices have been advanced year by year. A substrate material of a printed wiring board is required to have dielectric characteristics capable of reducing a transmission loss of a high-frequency signal (hereinafter, may be referred to as “high-frequency characteristics”), that is, a low relative dielectric constant and a low dielectric dissipation factor.

The present inventors have studied that, in order to improve the dielectric characteristics of the substrate material, a fluorine-containing resin having a low relative dielectric constant can be incorporated into a photosensitive resin film for forming an interlayer insulating layer. However, when only the fluorine-containing resin is incorporated into the photosensitive resin film, conductor adhesion, particularly adhesive strength with plated copper, may be reduced even when the relative dielectric constant of the interlayer insulating layer can be reduced. Therefore, it is difficult to achieve both excellent dielectric characteristics and excellent conductor adhesion.

In view of such current circumstances, an object of the present embodiment is to provide a photosensitive multilayer resin film capable of forming an interlayer insulating layer having excellent dielectric characteristics and excellent conductor adhesion, a printed wiring board using the photosensitive multilayer resin film and a method for producing the same, and a semiconductor package.

### Solution to Problem

As a result of studies to solve the above problems, the present inventors have found that the above problems can be solved by the present embodiment described below.

That is, the present embodiment relates to the following [1] to [13].
[1] A photosensitive multilayer resin film including:
a first resin composition layer; and
a second resin composition layer, in which
the first resin composition layer and the second resin composition layer each contain a compound (A) having an ethylenically unsaturated group, a thermosetting resin (B), a photopolymerization initiator (C), and an inorganic filler (D),
the second resin composition layer further contains a fluorine-containing resin (E), and
a fluorine atom concentration in the first resin composition layer is lower than a fluorine atom concentration in the second resin composition layer.
[2] The photosensitive multilayer resin film according to the above [1], in which the first resin composition layer and the second resin composition layer each contain a compound having an ethylenically unsaturated group and an acidic substituent as the compound (A) having an ethylenically unsaturated group.
[3] The photosensitive multilayer resin film according to the above [1] or [2], in which the first resin composition layer and the second resin composition layer each contain, as the thermosetting resin (B), one or more selected from the group consisting of an epoxy resin, a maleimide resin, an allyl resin, and a vinyl resin.
[4] The photosensitive multilayer resin film according to the above [3], in which the first resin composition layer and the second resin composition layer each contain an epoxy resin as the thermosetting resin (B), and a content of the epoxy resin in the first resin composition layer on a mass basis is greater than a content of the epoxy resin in the second resin composition layer on a mass basis.
[5] The photosensitive multilayer resin film according to any one of the above [1] to [4], in which the first resin composition layer contains silica as the inorganic filler (D), and a content of the silica in the first resin composition layer is 5 mass % to 70 mass %.
[6] The photosensitive multilayer resin film according to any of the above [1] to [5], in which the second resin composition layer contains silica having a true density of 1,500 kg/m³ or less as the inorganic filler (D).
[7] The photosensitive multilayer resin film according to any of the above [1] to [6], in which a content of the fluorine-containing resin (E) in the second resin composition layer is 10 mass % to 80 mass % based on a total amount of resin components in the second resin composition layer.
[8] The photosensitive multilayer resin film according to any of the above [1] to [7], in which the first resin composition layer and the second resin composition layer each further contain an elastomer (F).
[9] The photosensitive multilayer resin film according to any of the above [1] to [8], in which a layer formed by curing the first resin composition layer is a layer on which a circuit pattern is to be formed by copper plating, and the second resin composition layer is a layer having a surface to be attached when laminating the photosensitive multilayer resin film.
[10] The photosensitive multilayer resin film according to any of the above [1] to [9], which is used for forming an interlayer insulating layer having a photovia.
[11] A printed wiring board including:
an interlayer insulating layer which is a cured product of the photosensitive multilayer resin film according to any of the above [1] to [10].
[12] A semiconductor package including:
the printed wiring board according to the above [11].
[13] A method for producing a printed wiring board, including:
the following (1) to (4):
(1): laminating the photosensitive multilayer resin film according to any one of the above [1] to [10] on one surface or both surfaces of a circuit board in a state where the second resin composition layer serves as an attachment surface;
(2): forming an interlayer insulating layer having a via by exposing and developing the photosensitive multilayer resin film laminated in the (1);
(3): heating and curing the interlayer insulating layer having a via; and
(4): forming a circuit pattern on a layer of the interlayer insulating layer formed by curing the first resin composition layer.

### Advantageous Effects of Invention

According to the present embodiment, a photosensitive multilayer resin film capable of forming an interlayer insulating layer having excellent dielectric characteristics and excellent conductor adhesion, a printed wiring board using the photosensitive multilayer resin film and a method for producing the same, and a semiconductor package can be provided.

### BRIEF DESCRIPTION OF DRAWINGS

FIG. 1 is a schematic view showing one embodiment of a process for producing a printed wiring board using the photosensitive multilayer resin film of the present embodiment as a material for an interlayer insulating layer.

FIG. 2 is a cross-sectional SEM image for illustrating a measurement position of a fluorine atom concentration.

### DESCRIPTION OF EMBODIMENTS

In the numerical range described in the present description herein, the lower limit value and the upper limit value of the numerical range may be replaced with a value shown in Examples. In addition, the lower limit value and the upper limit value of the numerical range are arbitrarily combined with the lower limit value or the upper limit value of another numerical range, respectively. In the notation of the numerical range “AA to BB”, the numerical values AA and BB at both ends are included in the numerical range as the lower limit value and the upper limit value, respectively.

In the present description herein, for example, the description of “10 or more” means 10 and a numerical value exceeding 10, and the same applies to a case where the numerical value is different. Further, for example, the description of “10 or less” means 10 and a numerical value less than 10, and the same applies to a case where the numerical value is different.

In the present description herein, when there are a plurality of kinds of substances corresponding to each component, the content of each component means the total content of the plurality of kinds of substances, unless otherwise specified.

In the present description herein, the “solid content” means a nonvolatile content excluding a volatile substance such as a solvent. That is, the “solid content” refers to a component that remains without being volatilized when the resin composition is dried, and also includes liquid, syrup, and wax-like components at room temperature. In the present description herein, the room temperature means 25° C.

In the present description herein, the “number of ring carbon atoms” refers to the number of carbon atoms necessary for forming a ring, and does not include the number of carbon atoms of a substituent which the ring has. For example, both the cyclohexane skeleton and the methylcyclohexane skeleton have 6 ring carbon atoms.

The notation “(meth)acryl XX” means one or both of acryl XX and the corresponding methacryl XX. In addition, the “(meth)acryloyl group” means one or both of an acryloyl group and a methacryloyl group.

In the present description herein, for example, when a “layer” is described as in an interlayer insulating layer or the like, the “layer” includes not only an aspect of a solid layer but also an aspect in which a part of the layer has an island shape, an aspect in which a hole is opened, an aspect in which an interface with an adjacent layer is unclear, and the like.

The action mechanism described in the present description herein is a conjecture, and does not limit the mechanism by which the effect of the present embodiment is exhibited.

An aspect in which matters described in the present description herein are arbitrarily combined is also included in the present embodiment.

### [Photosensitive Multilayer Resin Film]

A photosensitive multilayer resin film of the present embodiment is a photosensitive multilayer resin film including: a first resin composition layer; and a second resin composition layer. The first resin composition layer and the second resin composition layer each contain a compound (A) having an ethylenically unsaturated group, a thermosetting resin (B), a photopolymerization initiator (C), and an inorganic filler (D). The second resin composition layer further contains a fluorine-containing resin (E). A fluorine atom concentration in the first resin composition layer is lower than a fluorine atom concentration in the second resin composition layer.

In the present description herein, each component may be appropriately referred to as “component (A)”, “component (B)”, or the like.

The first resin composition layer and the second resin composition layer in the photosensitive multilayer resin film of the present embodiment can form a pattern such as a via by exposure and development. Therefore, the photosensitive multilayer resin film of the present embodiment is suitable for forming an interlayer insulating layer having photovias. In the present description herein, the term “photovia” means a via formed by a photolithography method, that is, exposure and development.

The first resin composition layer contains the compound (A) having an ethylenically unsaturated group, the thermosetting resin (B), the photopolymerization initiator (C), and the inorganic filler (D).

The fluorine atom concentration in the first resin composition layer is lower than the fluorine atom concentration in the second resin composition layer. Accordingly, a layer formed by curing the first resin composition layer exhibits high adhesive strength with plated copper.

The reason for this is presumed as follows. The fluorine-containing resin (E) has high alkali resistance and is therefore less likely to be dissolved than other resin components in a roughening treatment step before forming plated copper. Therefore, it is considered that a surface containing a large amount of fluorine-containing resin (E) has a large amount of undissolved fluorine-containing resin (E) exposed on the surface after the roughening treatment step, which causes a decrease in adhesion to plated copper. On the other hand, it is considered that, in the photosensitive multilayer resin film of the present embodiment, the fluorine atom concentration in the first resin composition layer is lower than the fluorine atom concentration in the second resin composition layer, and therefore an amount of fluorine-containing resin (E) exposed on the surface of the first resin composition layer after the roughening treatment step can be reduced, and adhesion to plated copper on that surface can be improved.

The second resin composition layer contains the compound (A) having an ethylenically unsaturated group, the thermosetting resin (B), the photopolymerization initiator (C), the inorganic filler (D), and the fluorine-containing resin (E). Since the fluorine-containing resin (E) contained in the second resin composition layer has a small relative dielectric constant, a layer formed by curing the second resin composition layer contributes to improvement of dielectric characteristics of the interlayer insulating layer.

As described above, since the photosensitive multilayer resin film of the present embodiment includes the first resin composition layer that exhibits high adhesive strength with plated copper and the second resin composition layer that exhibits excellent dielectric characteristics, an interlayer insulating layer having excellent dielectric characteristics and excellent conductor adhesion can be formed. From the viewpoint of sufficiently exhibiting the effect, it is preferable that in the photosensitive multilayer resin film of the present embodiment, the layer formed by curing the first resin composition layer is a layer on which a circuit pattern is to be formed by copper plating, and the second resin composition layer is a layer having a surface to be attached when laminating the photosensitive multilayer resin film.

A thickness of the first resin composition layer is not particularly limited, and is preferably 0.1 μm to 50 μm, more preferably 0.5 μm to 30 μm, and still more preferably 1 μm to 10 μm, from the viewpoint of further improving a balance between the dielectric characteristics and the conductor adhesion.

A thickness of the second resin composition layer is not particularly limited, and is preferably 1 μm to 100 μm, more preferably 3 μm to 50 μm, and still more preferably 5 μm to 40 μm, from the viewpoint of further improving the balance between the dielectric characteristics and the conductor adhesion.

A thickness of the entire photosensitive multilayer resin film of the present embodiment is not particularly limited, and may be, for example, 2 μm to 110 μm, 4 μm to 60 μm, or 7 μm to 50 μm.

### <Fluorine Atom Concentration>

In the photosensitive multilayer resin film of the present embodiment, the fluorine atom concentration in the first resin composition layer (hereinafter, also referred to as “fluorine atom concentration in a first layer”) is lower than the fluorine atom concentration in the second resin composition layer (hereinafter, also referred to as “fluorine atom concentration in a second layer”).

The fluorine atom concentration in the first layer is not particularly limited, and is preferably 0 mass % to 7 mass %, more preferably 0 mass % to 6 mass %, and still more preferably 0 mass % to 5 mass %, from the viewpoint of forming an interlayer insulating layer excellent in dielectric characteristics and conductor adhesion.

The fluorine atom concentration in the second layer is not particularly limited as long as it is higher than the fluorine atom concentration in the first layer, and is preferably 8 mass % to 60 mass %, more preferably 10 mass % to 35 mass %, and still more preferably 15 mass % to 30 mass % in a range higher than the fluorine atom concentration in the first layer, from the viewpoint of forming an interlayer insulating layer excellent in dielectric characteristics and conductor adhesion.

A method for measuring the fluorine atom concentration in each layer is not particularly limited, and for example, the fluorine atom concentration can be measured by forming a cross section of a photosensitive multilayer resin film or a cured product thereof and performing elemental analysis of the cross section. More specifically, the fluorine atom concentration can be measured by a method described in Examples.

Hereinafter, each component contained in the first resin composition layer and the second resin composition layer will be described.

In the description related to the following components (A) to (I), a description related to a preferred embodiment of the component which may be contained in both the first resin composition layer and the second resin composition layer is common to the first resin composition layer and the second resin composition layer unless otherwise specified.

In the following components (A) to (I), the components contained in the first resin composition layer and the second resin composition layer may be the same as or different from each other. That is, for example, the component (A) contained in the first resin composition layer and the component (A) contained in the second resin composition layer may be the same as or different from each other. The same applies to the components (B) to (I).

### <(A) Compound Having Ethylenically Unsaturated Group>

The component (A) is not particularly limited as long as it is a compound having an ethylenically unsaturated group.

The component (A) may be used alone or may be used in combination of two or more types.

The component (A) has an ethylenically unsaturated group and thus exhibits photopolymerizability, particularly radical polymerizability.

In the present description herein, the term “ethylenically unsaturated group” means a substituent containing an ethylenically unsaturated bond. The term “ethylenically unsaturated bond” means a carbon-carbon double bond capable of an addition reaction, and does not include a double bond of an aromatic ring.

Examples of the ethylenically unsaturated group include a vinyl group, an allyl group, a (meth)acryloyl group, a propargyl group, a butenyl group, an ethynyl group, a phenylethynyl group, a maleimide group, and a nadimide group. Among them, a (meth)acryloyl group is preferable from the viewpoint of reactivity.

The first resin composition layer and the second resin composition layer each preferably contain a compound (A1) having an ethylenically unsaturated group and an acidic substituent from the viewpoint of enabling alkali development, and preferably contain the component (A1) and a monomer (A2) having two or more ethylenically unsaturated groups from the viewpoint of forming an interlayer insulating layer excellent in heat resistance and dielectric characteristics. Hereinafter, the component (A1) and the component (A2) will be described.

### <(A1) Compound Having Ethylenically Unsaturated Group and Acidic Substituent>

Examples of the acidic substituent of the component (A1) include a carboxy group, a sulfonic acid group, and a phenolic hydroxy group. Among them, a carboxy group is preferable from the viewpoint of resolution.

An acid value of the component (A1) is not particularly limited, and is preferably 20 mgKOH/g to 200 mgKOH/g, more preferably 40 mgKOH/g to 180 mgKOH/g, and still more preferably 70 mgKOH/g to 150 mgKOH/g.

When the acid value of the component (A1) is equal to or greater than the lower limit value, alkali developability tends to be better. When the acid value of the component (A1) is equal to or lower than the upper limit value, the relative dielectric constant tends to be better.

The acid value of the component (A1) can be measured by a method described in Examples.

A weight-average molecular weight (Mw) of the component (A1) is not particularly limited, and is preferably 600 to 30,000, more preferably 800 to 20,000, still more preferably 1,000 to 10,000, and particularly preferably 1,200 to 4,000.

When the weight-average molecular weight (Mw) of the component (A1) is in the above range, an interlayer insulating layer excellent in adhesive strength with plated copper, heat resistance, and insulation reliability tends to be formed.

In the present description herein, the weight-average molecular weight (Mw) is a value determined by gel permeation chromatography (GPC) using tetrahydrofuran as a solvent in terms of standard polystyrene, and specifically a value measured according to a method described in Examples.

The component (A1) preferably contains an alicyclic skeleton from the viewpoint of a low relative dielectric constant and a low dielectric dissipation factor.

The alicyclic skeleton of the component (A1) is preferably an alicyclic skeleton having 5 to 20 ring carbon atoms, more preferably an alicyclic skeleton having 5 to 18 ring carbon atoms, still more preferably an alicyclic skeleton having 6 to 16 ring carbon atoms, particularly preferably an alicyclic skeleton having 7 to 14 ring carbon atoms, and most preferably an alicyclic skeleton having 8 to 12 ring carbon atoms, from the viewpoint of the resolution and the dielectric characteristics.

The alicyclic skeleton of the component (A1) is preferably composed of two or more rings, more preferably composed of two to four rings, and still more preferably composed of three rings, from the viewpoint of the resolution and the dielectric characteristics. Examples of the alicyclic skeleton composed of two or more rings include a norbornane skeleton, a decalin skeleton, a bicycloundecane skeleton, and a saturated dicyclopentadiene skeleton. Among them, a saturated dicyclopentadiene skeleton is preferable from the viewpoint of the resolution and the dielectric characteristics.

From the same viewpoint, the component (A1) preferably contains an alicyclic skeleton represented by the following general formula (A1-1).

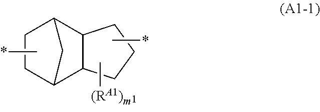

(In the formula, R^{A1} represents an alkyl group having 1 to 12 carbon atoms, and may be substituted at any position in the alicyclic skeleton. m¹ is an integer of 0 to 6. * represents a binding site).

Examples of the alkyl group having 1 to 12 carbon atoms and represented by R^{A1} in the general formula (A1-1) include a methyl group, an ethyl group, an n-propyl group, an isopropyl group, a n-butyl group, an isobutyl group, a t-butyl group, and an n-pentyl group. The alkyl group is preferably an alkyl group having 1 to 6 carbon atoms, more preferably an alkyl group having 1 to 3 carbon atoms, and still more preferably a methyl group.

In the general formula (A1-1), m¹ is an integer of 0 to 6, preferably an integer of 0 to 2, and more preferably 0. When m¹ is an integer of 2 to 6, a plurality of R^{A1}'s may be the same as or different from each other. Further, a plurality of R^{A1}'s may be substituted on the same carbon atom to the extent possible, or may be substituted on different carbon atoms.

In the general formula (A1-1), * represents a binding site to another structure.

A single bond having the binding site * may be bonded to any carbon atom on the alicyclic skeleton, and is preferably bonded to a carbon atom represented by 1 or 2 and a carbon atom represented by 3 or 4 in the following general formula (A1-1′).

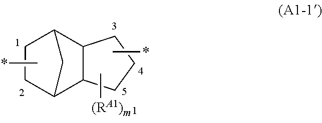

(In the formula, R^{A1}, m¹, and * are the same as those in the general formula (A1-1)).

The component (A1) is preferably a compound obtained by reacting a saturated group or unsaturated group-containing polybasic acid anhydride (a3) with a compound obtained by reacting an epoxy resin (a1) with a (meth)acryloyl group-containing organic acid (a2).

In the following description, the compound obtained by reacting the epoxy resin (a1) with the (meth)acryloyl group-containing organic acid (a2) may be referred to as “component (A′)”.

A compound obtained by reacting the component (A′) with the saturated group or unsaturated group-containing polybasic acid anhydride (a3) may be referred to as “acid-modified (meth)acryloyl group-containing epoxy resin derivative”.

Hereinafter, preferred embodiments of the component (A1) will be described.

((a1) Epoxy Resin)

The epoxy resin (a1) preferably has two or more epoxy groups.

The epoxy resin (a1) may be used alone or may be used in combination of two or more types.

The epoxy resin (a1) is classified into, for example, a glycidyl ether type epoxy resin, a glycidyl amine type epoxy resin, and a glycidyl ester type epoxy resin. Among them, a glycidyl ether type epoxy resin is preferable.

The epoxy resin (a1) can be classified into various epoxy resins depending on a difference in the main skeleton, and can be classified into, for example, an epoxy resin having an alicyclic skeleton, a novolac type epoxy resin, a bisphenol type epoxy resin, an aralkyl type epoxy resin, and other epoxy resins. Among them, an epoxy resin having an alicyclic skeleton and a novolac type epoxy resin are preferable.

### [Epoxy Resin Having Alicyclic Skeleton]

The alicyclic skeleton of the epoxy resin having an alicyclic skeleton is described in the same manner as the alicyclic skeleton of the above-described component (A1), and preferred embodiments thereof are also the same.

The epoxy resin having an alicyclic skeleton is preferably an epoxy resin represented by the following general formula (A1-2).

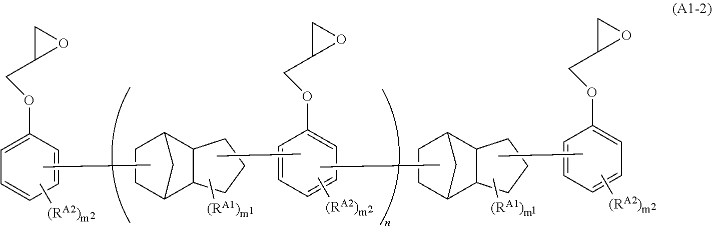

(In the formula, R^{A1}'s each independently represent an alkyl group having 1 to 12 carbon atoms, and may be substituted at any position in the alicyclic skeleton. R^{A2}'s each independently represent an alkyl group having 1 to 12 carbon atoms. m¹ is an integer of 0 to 6, and m² is an integer of 0 to 3. n is a number of 0 to 50).

In the general formula (A1-2), R^{A1} is the same as R^{A1} in the general formula (A1-1), and preferred embodiments thereof are also the same.

Examples of the alkyl group having 1 to 12 carbon atoms and represented by R^{A2} in the general formula (A1-2) include a methyl group, an ethyl group, an n-propyl group, an isopropyl group, a n-butyl group, an isobutyl group, a t-butyl group, and an n-pentyl group. The alkyl group is preferably an alkyl group having 1 to 6 carbon atoms, more preferably an alkyl group having 1 to 3 carbon atoms, and still more preferably a methyl group.

In the general formula (A1-2), m¹ is the same as m¹ in the general formula (A1-1), and preferred embodiments thereof are also the same.

In the general formula (A1-2), m² is an integer of 0 to 3, preferably 0 or 1, and more preferably 0.

In the general formula (A1-2), n represents a number of structural units in parentheses, and is a number of 0 to 50. In general, the epoxy resin is a mixture of those having different numbers of the structural unit in the parentheses, and in this case, n is represented by an average value of the mixture. n is preferably a number of 0 to 30.

As the epoxy resin having an alicyclic skeleton, a commercially available product may be used, and examples of the commercially available product include “ZXR-1807H” (trade name, manufactured by Nippon Kayaku Co., Ltd.), “XD-1000” (trade name, manufactured by Nippon Kayaku Co., Ltd.), and “EPICLON (registered trademark) HP-7200” (trade name, manufactured by DIC Corporation).

### [Novolac Type Epoxy Resin]

Examples of the novolac type epoxy resin include bisphenol novolac type epoxy resins such as a bisphenol A novolac type epoxy resin, a bisphenol F novolac type epoxy resin, and a bisphenol S novolac type epoxy resin; and phenol novolac type epoxy resins, cresol novolac type epoxy resins, biphenyl novolac type epoxy resins, and naphthol novolac type epoxy resins.

As the novolac type epoxy resin, an epoxy resin having a structural unit represented by the following general formula (A1-3) is preferable.

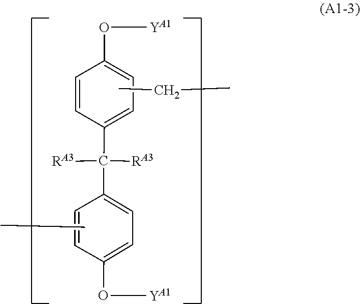

(In the formula, R^{A3}'s each independently represent a hydrogen atom or a methyl group, and Y^{A1}'s each independently represent a hydrogen atom or a glycidyl group. At least one of the two Y^{A1}'s is a glycidyl group).

From the viewpoint of the resolution, it is preferable that each of R^{A3}'s in the general formula (A1-3) is a hydrogen atom. From the same viewpoint, it is preferable that each of Y^{A1}'s in the general formula (A1-3) is a glycidyl group.

The number of structural units in the epoxy resin (a1) having a structural unit represented by the general formula (A1-3) is 1 or more, preferably 10 to 100, more preferably 13 to 80, and still more preferably 15 to 70. When the number of structural units is within the above range, an interlayer insulating layer excellent in conductor adhesion, heat resistance, and insulation reliability tends to be formed.

As the epoxy resin having a structural unit represented by the general formula (A1-3), a commercially available product may be used, and examples of the commercially available product include “EXA-7376” series (trade name, an epoxy resin in which each of R^{A3}'s is a hydrogen atom and each of Y^{A1}'s is a glycidyl group in the general formula (A1-3), manufactured by DIC Corporation), and “EPON SU8” series (trade name, an epoxy resin in which each of R^{A3}'s is a methyl group and each of Y^{A1}'s is a glycidyl group in the general formula (A1-3), manufactured by Mitsubishi Chemical Corporation).

### [Bisphenol Type Epoxy Resin]

Examples of the bisphenol type epoxy resin include a bisphenol A type epoxy resin, a bisphenol F type epoxy resin, a bisphenol S type epoxy resin, and 3,3′,5,5′-tetramethyl-4,4′-diglycidyloxydiphenylmethane.

### [Aralkyl Type Epoxy Resin]

Examples of the aralkyl type epoxy resin include a phenolaralkyl type epoxy resin, a biphenyl aralkyl type epoxy resin, and a naphtholaralkyl type epoxy resin.

### [Other Epoxy Resins]

Examples of the other epoxy resins include a stilbene type epoxy resin, a naphthalene type epoxy resin, a naphthylene type epoxy resin, a biphenyl type epoxy resin, a dihydroanthracene type epoxy resin, a cyclohexanedimethanol type epoxy resin, a trimethylol type epoxy resin, an alicyclic epoxy resin, an aliphatic linear epoxy resin, a heterocyclic epoxy resin, a spiro-ring-containing epoxy resin, and a rubber-modified epoxy resin.

((a2) (Meth)Acryloyl Group-Containing Organic Acid)

As the (meth)acryloyl group-containing organic acid (a2), a (meth)acryloyl group-containing monocarboxylic acid is preferable.

Examples of the (meth)acryloyl group-containing monocarboxylic acid include acrylic acid derivatives such as acrylic acid, a dimer of acrylic acid, methacrylic acid, β-furfuryl acrylic acid, β-styryl acrylic acid, cinnamic acid, crotonic acid, and α-cyanocinnamic acid; a half-ester compound which is a reaction product of a hydroxy group-containing acrylate and a dibasic acid anhydride; and a half-ester compound which is a reaction product of a (meth)acryloyl group-containing monoglycidyl ether or a (meth)acryloyl group-containing monoglycidyl ester and a dibasic acid anhydride.

The component (a2) may be used alone or may be used in combination of two or more types.

In the reaction between the component (a1) and the component (a2), an amount of the component (a2) to be used is not particularly limited, and is preferably 0.6 equivalents to 1.1 equivalents, more preferably 0.8 equivalents to 1.05 equivalents, and still more preferably 0.9 equivalents to 1.02 equivalents, with respect to 1 equivalent of the epoxy group of the component (a1). By reacting the component (a1) with the component (a2) at the above-described ratio, the polymerizability of the component (A1) is improved, and the resolution tends to be improved.

It is preferable that the component (a1) and the component (a2) are dissolved in an organic solvent and reacted while heating. In the reaction, a known reaction catalyst, a polymerization inhibitor, or the like may be used as necessary.

When a (meth)acryloyl group-containing monocarboxylic acid is used as the component (a2), the component (A′) obtained by reacting the component (a1) and the component (a2) has a hydroxy group formed by a ring-opening addition reaction of the epoxy group of the component (a1) and the carboxy group of the component (a2). Next, the component (A′) is reacted with the saturated group or unsaturated group-containing polybasic acid anhydride (a3) to obtain an acid-modified (meth)acryloyl group-containing epoxy resin derivative in which a hydroxy group of the component (A′) and an acid anhydride group of the component (a3) are half-esterified. The hydroxy group contained in the component (A′) may include a hydroxy group originally present in the component (a1).

((a3) Polybasic Acid Anhydrate)

The component (a3) may be one containing a saturated group or one containing an unsaturated group. Examples of the component (a3) include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride. Among them, tetrahydrophthalic anhydride is preferable from the viewpoint of the resolution. The component (a3) may be used alone or may be used in combination of two or more types.

In the reaction between the component (A′) and the component (a3), for example, the acid value of the acid-modified (meth)acryloyl group-containing epoxy resin derivative can be well adjusted by reacting 0.1 equivalents to 1.0 equivalent of the component (a3) with respect to 1 equivalent of the hydroxy group in the component (A′).

### <(A2) Monomer Having Two or More Ethylenically Unsaturated Groups>

The component (A2) is mainly used as a crosslinking agent of the component (A1).

The first resin composition layer and the second resin composition layer each contain the component (A1) and the component (A2), and thus a crosslinking density due to a photoradical polymerization reaction increases, the resistance to an alkali developer and the resolution are improved, and an interlayer insulating layer excellent in heat resistance tends to be formed.

The component (A2) may or may not have an acidic substituent.

The number of the ethylenically unsaturated groups of the component (A2) is 2 or more, and is preferably 2 to 10, more preferably 2 to 8, and still more preferably 2 to 7, from the viewpoint of the resolution and the viewpoint of forming an interlayer insulating layer excellent in heat resistance and dielectric characteristics.

Examples of the component (A2) include a bifunctional monomer having two ethylenically unsaturated groups and a polyfunctional monomer having three or more ethylenically unsaturated groups.

Examples of the bifunctional monomer having two ethylenically unsaturated groups include aliphatic di(meth)acrylates such as trimethylolpropane di(meth)acrylate, polypropylene glycol di(meth)acrylate, and polyethylene glycol di(meth)acrylate; di(meth)acrylates having an alicyclic skeleton, such as dicyclopentadiene di(meth)acrylate and tricyclodecane dimethanol di(meth)acrylate; and aromatic di(meth)acrylates such as 2,2-bis(4-(meth)acryloxypolyethoxypolypropoxyphenyl) propane, and bisphenol A diglycidyl ether di(meth)acrylate.

Examples of the polyfunctional monomer having three or more ethylenically unsaturated groups include (meth)acrylate compounds having a skeleton derived from trimethylolpropane, such as trimethylolpropane tri(meth)acrylate; (meth)acrylate compounds having a skeleton derived from tetramethylolmethane, such as tetramethylolmethane tri(meth)acrylate and tetramethylolmethane tetra(meth)acrylate; (meth)acrylate compounds having a skeleton derived from pentaerythritol, such as pentaerythritol tri(meth)acrylate and pentaerythritol tetra(meth)acrylate; (meth)acrylate compounds having a skeleton derived from dipentaerythritol, such as dipentaerythritol penta (meth)acrylate and dipentaerythritol hexa (meth)acrylate; (meth)acrylate compounds having a skeleton derived from ditrimethylolpropane, such as ditrimethylolpropane tetra(meth)acrylate; and (meth)acrylate compounds having a skeleton derived from diglycerin.

Here, the above-described “(meth)acrylate compound having a skeleton derived from XXX” (in which XXX is a compound name) means an esterified product of XXX and (meth)acrylic acid, and the esterified product also includes a compound modified with an alkyleneoxy group.

Among the above options, from the viewpoint of the resolution and the viewpoint of forming an interlayer insulating layer excellent in conductor adhesion, the component (A2) is preferably a polyfunctional monomer having three or more ethylenically unsaturated groups, and more preferably a (meth)acrylate compound having a skeleton derived from trimethylol propane or a (meth)acrylate compound having a skeleton derived from dipentaerythritol.

The component (A) may or may not contain a compound other than the component (A1) and the component (A2). Examples of the component other than the component (A1) and the component (A2) include a monofunctional monomer having one ethylenically unsaturated group and having no acidic substituent.

### (Content of Component (A) in First Resin Composition Layer)

A content of the component (A) in the first resin composition layer is not particularly limited, and is preferably 10 mass % to 80 mass %, more preferably 20 mass % to 60 mass %, and still more preferably 30 mass % to 50 mass %, based on a total amount of resin components in the first resin composition layer, from the viewpoint of the resolution of the photosensitive multilayer resin film and the dielectric characteristics of the interlayer insulating layer to be formed.

Here, in the present description herein, the term “resin component” means a resin and a compound which forms a resin by a curing reaction. For example, in the photosensitive multilayer resin film of the present embodiment, the component (A), the component (B), the component (E), and the component (F) are classified into the resin component.

On the other hand, the component (C), the component (D), a component (G), and a component (H) are not included in the resin component.

When the first resin composition layer contains the component (A1), a content of the component (A1) in the first resin composition layer is not particularly limited, and is preferably 5 mass % to 70 mass %, more preferably 10 mass % to 50 mass %, and still more preferably 20 mass % to 40 mass %, based on the total amount of the resin components in the first resin composition layer, from the viewpoint of the resolution and the dielectric characteristics of the interlayer insulating layer to be formed.

When the first resin composition layer contains the component (A1) and the component (A2), a content of the component (A2) in the first resin composition layer is not particularly limited, and is preferably 5 parts by mass to 120 parts by mass, more preferably 10 parts by mass to 60 parts by mass, and still more preferably 20 parts by mass to 40 parts by mass, with respect to 100 parts by mass of the component (A1) in the first resin composition layer, from the viewpoint of the resolution and the dielectric characteristics of the interlayer insulating layer to be formed.

### (Content of Component (A) in Second Resin Composition Layer)

A content of the component (A) in the second resin composition layer is not particularly limited, and is preferably 10 mass % to 80 mass %, more preferably 15 mass % to 60 mass %, and still more preferably 20 mass % to 50 mass %, based on a total amount of resin components in the second resin composition layer, from the viewpoint of the resolution and the dielectric characteristics of the interlayer insulating layer to be formed.

When the second resin composition layer contains the component (A1), a content of the component (A1) in the second resin composition layer is not particularly limited, and is preferably 3 mass % to 60 mass %, more preferably 5 mass % to 40 mass %, and still more preferably 10 mass % to 30 mass %, based on the total amount of the resin components in the second resin composition layer, from the viewpoint of the resolution and the dielectric characteristics of the interlayer insulating layer to be formed.

When the second resin composition layer contains the component (A1) and the component (A2), a content of the component (A2) in the second resin composition layer is not particularly limited, and is preferably 20 parts by mass to 100 parts by mass, more preferably 40 parts by mass to 90 parts by mass, and still more preferably 60 parts by mass to 80 parts by mass, with respect to 100 parts by mass of the component (A1) in the second resin composition layer, from the viewpoint of the resolution and the dielectric characteristics of the interlayer insulating layer to be formed.

### <(B) Thermosetting Resin>

The thermosetting resin (B) is not particularly limited as long as it is a resin having a thermosetting property.

When the first resin composition layer and the second resin composition layer each contain the thermosetting resin (B), the heat resistance of the interlayer insulating layer to be formed tends to be improved.

The thermosetting resin (B) may be used alone or may be used in combination of two or more types.

Examples of the thermosetting resin (B) include an epoxy resin, an isocyanate resin, a maleimide resin, a phenolic resin, a cyanate resin, a benzoxazine resin, an oxetane resin, an amino resin, an unsaturated polyester resin, an allyl resin, a vinyl resin, a dicyclopentadiene resin, a silicone resin, a triazine resin, a melamine resin, and other known thermosetting resins.

Among the above options, from the viewpoint of forming an interlayer insulating layer excellent in heat resistance and conductor adhesion, the first resin composition layer and the second resin composition layer each preferably contain, as the component (B), one or more resins selected from the group consisting of an epoxy resin, a maleimide resin, an allyl resin, and a vinyl resin, and more preferably contain an epoxy resin.

From the viewpoint of forming an interlayer insulating layer excellent in heat resistance and conductor adhesion, the second resin composition layer also preferably contains a maleimide resin.

### (Epoxy Resin)

The epoxy resin is preferably an epoxy resin having two or more epoxy groups.

The epoxy resin is classified into a glycidyl ether type epoxy resin, a glycidyl amine type epoxy resin, and a glycidyl ester type epoxy resin. Among them, a glycidyl ether type epoxy resin is preferable.

In addition, epoxy resins are classified into various epoxy resins according to the difference in the main skeleton, and the respective types of epoxy resins are further classified as follows. Specifically, epoxy resins are classified into, for example, bisphenol-based epoxy resins such as bisphenol A type epoxy resin, bisphenol F type epoxy resin, and bisphenol S type epoxy resin; bisphenol-based novolac type epoxy resins such as bisphenol A novolac type epoxy resin and bisphenol F novolac type epoxy resin; novolac type epoxy resins other than the above-mentioned bisphenol-based novolac type epoxy resins, such as phenol novolac type epoxy resin, cresol novolac type epoxy resin, and biphenyl novolac type epoxy resin; phenol aralkyl type epoxy resins; stilbene type epoxy resins; naphthalene skeleton-containing epoxy resins such as naphthol novolac type epoxy resin, naphthol type epoxy resin, naphthol aralkyl type epoxy resin, and naphthylene ether type epoxy resin; biphenyl type epoxy resins; biphenyl aralkyl type epoxy resins; xylylene type epoxy resins; dihydroanthracene type epoxy resins; alicyclic epoxy resins such as saturated dicyclopentadiene type epoxy resins; heterocyclic epoxy resins; spiro ring-containing epoxy resins; cyclohexanedimethanol type epoxy resins; trimethylol type epoxy resins; aliphatic chain epoxy resins; and rubber-modified epoxy resins.

Among them, the epoxy resin is preferably a bisphenol-based epoxy resin, a naphthalene skeleton-containing epoxy resin, or a biphenyl aralkyl type epoxy resin, and more preferably a naphthalene skeleton-containing epoxy resin or a biphenyl aralkyl type epoxy resin.

### (Isocyanate Resin)

Examples of the isocyanate resin include aliphatic isocyanates such as trimethylene diisocyanate, tetramethylene diisocyanate, pentamethylene diisocyanate, hexamethylene diisocyanate, and trimethylhexamethylene diisocyanate; alicyclic isocyanates such as 1,3-cyclopentane diisocyanate, 1,4-cyclohexane diisocyanate, 1,2-cyclohexane diisocyanate, isophorone diisocyanate, and norbornane diisocyanate; aromatic isocyanates such as xylylene diisocyanate, 2,4-tolylene diisocyanate, and 2,6-tolylene diisocyanate; biuret forms thereof; and nurate forms thereof. Among them, aliphatic isocyanates are preferable, and hexamethylene diisocyanate is more preferable.

### (Maleimide Resin)

Examples of the maleimide resin include an aromatic maleimide compound having an N-substituted maleimide group directly bonded to an aromatic ring, and an aliphatic maleimide compound having an N-substituted maleimide group directly bonded to an aliphatic hydrocarbon group. Among them, from the viewpoint of the heat resistance and handleability, an aromatic maleimide compound is preferable, and an aromatic bismaleimide compound is more preferable.

Examples of the aromatic maleimide compound include bis(4-maleimidophenyl) methane, 2,2-bis [4-(4-maleimidophenoxy)phenyl]propane, 3,3′-dimethyl-5,5′-diethyl-4,4′-diphenylmethane bismaleimide, polyphenylmethane maleimide, a biphenylaralkyl type maleimide resin, and an aromatic bismaleimide resins having an indane skeleton. Among them, an aromatic bismaleimide resin having an indane skeleton is preferable.

### (Content of Component (B) in First Resin Composition Layer)

A content of the thermosetting resin (B) in the first resin composition layer is not particularly limited, and is preferably 10 mass % to 90 mass %, more preferably 30 mass % to 80 mass %, and still more preferably 40 mass % to 70 mass %, based on the total amount of the resin components in the first resin composition layer, from the viewpoint of forming an interlayer insulating layer excellent in conductor adhesion and heat resistance.

When the first resin composition layer contains an epoxy resin as the thermosetting resin (B), a content of the epoxy resin in the first resin composition layer is not particularly limited, and is preferably 10 mass % to 80 mass %, more preferably 20 mass % to 70 mass %, and still more preferably 30 mass % to 60 mass %, based on the total amount of the resin components in the first resin composition layer, from the viewpoint of forming an interlayer insulating layer excellent in conductor adhesion and heat resistance.

The content of the epoxy resin in the first resin composition layer on a mass basis is preferably larger than the content of the epoxy resin in the second resin composition layer on a mass basis, from the viewpoint of forming an interlayer insulating layer excellent in conductor adhesion.

When the first resin composition layer contains an isocyanate resin as the thermosetting resin (B), a content of the isocyanate resin in the first resin composition layer is not particularly limited, and is preferably 1 mass % to 30 mass %, more preferably 3 mass % to 20 mass %, and still more preferably 5 mass % to 15 mass %, based on the total amount of the resin components in the first resin composition layer, from the viewpoint of forming an interlayer insulating layer excellent in conductor adhesion and heat resistance.

### (Content of Component (B) in Second Resin Composition Layer)

A content of the thermosetting resin (B) in the second resin composition layer is not particularly limited, and is preferably 1 mass % to 50 mass %, more preferably 5 mass % to 40 mass %, and still more preferably 10 mass % to 30 mass %, based on the total amount of the resin components in the second resin composition layer, from the viewpoint of forming an interlayer insulating layer excellent in heat resistance and dielectric characteristics.

When the second resin composition layer contains an epoxy resin as the thermosetting resin (B), a content of the epoxy resin in the second resin composition layer is not particularly limited, and is preferably 1 mass % to 50 mass %, more preferably 3 mass % to 30 mass %, and still more preferably 5 mass % to 20 mass %, based on the total amount of the resin components in the second resin composition layer, from the viewpoint of forming an interlayer insulating layer excellent in heat resistance and dielectric characteristics.

When the second resin composition layer contains an isocyanate resin as the thermosetting resin (B), a content of the isocyanate resin in the second resin composition layer is not particularly limited, and is preferably 1 mass % to 20 mass %, more preferably 2 mass % to 15 mass %, and still more preferably 4 mass % to 10 mass %, based on the total amount of the resin components in the second resin composition layer, from the viewpoint of forming an interlayer insulating layer excellent in heat resistance and dielectric characteristics.

When the second resin composition layer contains a maleimide resin as the thermosetting resin (B), a content of the maleimide resin in the second resin composition layer is not particularly limited, and is preferably 1 mass % to 40 mass %, more preferably 3 mass % to 30 mass %, and still more preferably 5 mass % to 20 mass %, based on the total amount of the resin components in the second resin composition layer, from the viewpoint of forming an interlayer insulating layer excellent in heat resistance and dielectric characteristics.

### <(C) Photopolymerization Initiator>

The photopolymerization initiator (C) is mainly a polymerization initiator for a photoradical polymerization reaction of an ethylenically unsaturated group of the component (A).

When the first resin composition layer and the second resin composition layer each contain the photopolymerization initiator (C), the resolution tends to be further improved.

The photopolymerization initiator (C) may be used alone or may be used in combination of two or more types.

Examples of the photopolymerization initiator (C) include benzoin-based compounds such as benzoin, benzoin methyl ether, and benzoin isopropyl ether; acetophenone-based compounds such as acetophenone, 2,2-dimethoxy-2-phenylacetophenone, 2,2-diethoxy-2-phenylacetophenone, 1,1-dichloroacetophenone, 1-hydroxycyclohexyl phenyl ketone, 2-benzyl-2-dimethylamino-1-(4-morpholinophenyl)-1-butanone, 2-[4-(methylthio)benzoyl]-2-(4-morpholinyl) propane, and N,N-dimethylaminoacetophenone; anthraquinone-based compounds such as 2-methylanthraquinone, 2-ethylanthraquinone, 2-tert-butylanthraquinone, 1-chloroanthraquinone, 2-amylanthraquinone, and 2-aminoanthraquinone; ketal-based compounds such as acetophenonedimethylketal and benzyldimethylketal; acridine-based compounds such as 9-phenylacridine and 1,7-bis(9,9′-acridinyl) heptane; acylphosphine oxide-based compounds such as phenylbis(2,4,6-trimethylbenzoyl) phosphine oxide; and oxime ester-based compounds such as 1,2-octanedione-1-[4-(phenylthio)phenyl]-2-(O-benzoyloxime), 1-[9-ethyl-6-(2-methylbenzoyl)-9H-carbazol-3-yl]ethanone 1-(O-acetyloxime), and 1-phenyl-1,2-propanedione-2-[O-(ethoxycarbonyl) oxime]; thioxanthone compounds such as 2,4-dimethylthioxanthone, 2,4-diethylthioxanthone, 2-chlorothioxanthone, and 2,4-diisopropylthioxanthone; and benzophenone compounds such as 4,4′-bis(dimethylamino)benzophenone and 4,4′-bis(diethylamino)benzophenone. Among them, phenylbis(2,4,6-trimethylbenzoyl) phosphine oxide and 1-[9-ethyl-6-(2-methylbenzoyl)-9H-carbazol-3-yl]ethanone 1-(O-acetyloxime) are preferable.

### (Content of Component (C) in First Resin Composition Layer)

A content of the photopolymerization initiator (C) in the first resin composition layer is not particularly limited, and is preferably 0.01 parts by mass to 10 parts by mass, more preferably 0.05 parts by mass to 5 parts by mass, and still more preferably 0.1 parts by mass to 1 part by mass, with respect to 100 parts by mass of the component (A) in the first resin composition layer, from the viewpoint of easily obtaining an appropriate accelerating effect of the polymerization reaction.

### (Content of Component (C) in Second Resin Composition Layer)

A content of the photopolymerization initiator (C) in the second resin composition layer is not particularly limited, and is preferably 0.01 parts by mass to 10 parts by mass, more preferably 0.05 parts by mass to 5 parts by mass, and still more preferably 0.1 parts by mass to 1 part by mass, with respect to 100 parts by mass of the component (A) in the second resin composition layer, from the viewpoint of easily obtaining an appropriate accelerating effect of the polymerization reaction.

### <(D) Inorganic Filler>

When the first resin composition layer and the second resin composition layer each contain the inorganic filler (D), the interlayer insulating layer to be formed tends to have further improved low thermal expansion, heat resistance, and flame retardancy.

The inorganic filler (D) can be used alone or in combination of two or more types.

In the photosensitive multilayer resin film of the present embodiment, the first resin composition layer preferably contains silica as the inorganic filler (D). Accordingly, a layer formed by curing the first resin composition layer exhibits high adhesive strength with plated copper.

The second resin composition layer also preferably contains silica from the viewpoint of forming an interlayer insulating layer excellent in low thermal expansion, heat resistance, and flame retardancy.

The silica may be surface-treated with a coupling agent such as a silane coupling agent.

Examples of the silica include precipitated silica produced by a wet method and having a high water content, and dry process silica produced by a dry process and containing almost no bound water. Further, examples of the dry process silica include crushed silica, fumed silica, and fused silica, for example, depending on the difference in the production method.

Examples of the silica include silica (D1) having a true density of more than 1,500 kg/m³ (hereinafter, also referred to as “component (D1)”) and silica (D2) having a true density of 1,500 kg/m³ or less (hereinafter, also referred to as “component (D2)”).

The component (D1) tends to have a low dielectric dissipation factor. Therefore, from the viewpoint of forming an interlayer insulating layer excellent in dielectric characteristics, the first resin composition layer preferably contains the component (D1).

From the viewpoint of the low thermal expansion, the true density of the silica which is the component (D1) is preferably more than 1,500 kg/m³ and 2,200 kg/m³ or less, more preferably 1,600 kg/m³ to 2,200 kg/m³, and still more preferably 1,800 kg/m³ to 2,200 kg/m³.

The component (D2) tends to have a small relative dielectric constant. Therefore, from the viewpoint of forming an interlayer insulating layer excellent in dielectric characteristics, the second resin composition layer preferably contains the component (D2).

From the viewpoint of the dielectric characteristics, the true density of the silica which is the component (D2) is preferably 1,000 kg/m³ to 1,500 kg/m³, more preferably 1,100 kg/m³ to 1,500 kg/m³, still more preferably 1,200 kg/m³ to 1,500 kg/m³, particularly preferably 1,250 kg/m³ to 1,450 kg/m³, and most preferably 1,250 kg/m³ to 1,400 kg/m³.

The true density of silica can be measured with a dry automatic density meter “AccuPycII 1340” (manufactured by Shimadzu Corporation).

Examples of the inorganic filler (D) other than silica include, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, and silicon carbide.

A volume-average particle diameter (D50) of the inorganic filler (D) is not particularly limited, and is preferably 0.01 μm to 3.0 μm, more preferably 0.1 μm to 2.5 μm, and still more preferably 0.3 μm to 2.0 μm, from the viewpoint of the resolution.

In the present description herein, the volume-average particle diameter (D₅₀) can be obtained as a particle diameter corresponding to an integrated value of 50% (volume-based) in a particle size distribution by measuring particles dispersed in a solvent at a refractive index of 1.38 in accordance with International Standard ISO13321 using a submicron particle analyzer (trade name: N5, manufactured by Beckman Coulter, Inc.).

### (Content of Inorganic Filler (D) in First Resin Composition Layer)

A content of the inorganic filler (D) in the first resin composition layer is not particularly limited, and is preferably 5 mass % to 70 mass %, more preferably 15 mass % to 60 mass %, and still more preferably 25 mass % to 50 mass %, from the viewpoint of forming an interlayer insulating layer excellent in low thermal expansion, heat resistance, flame retardancy, and conductor adhesion.

When the first resin composition layer contains silica, a content of the silica in the first resin composition layer is not particularly limited, and is preferably 5 mass % to 70 mass %, more preferably 15 mass % to 60 mass %, and still more preferably 25 mass % to 50 mass %, from the viewpoint of forming an interlayer insulating layer excellent in low thermal expansion, heat resistance, flame retardancy, and conductor adhesion.

The content of the silica in the first resin composition layer on a mass basis is preferably larger than the content of the silica in the second resin composition layer on a mass basis from the viewpoint of forming an interlayer insulating layer excellent in conductor adhesion.

When the first resin composition layer contains the component (D1), a content of the component (D1) in the first resin composition layer is not particularly limited, and is preferably 60 mass % to 100 mass %, more preferably 70 mass % to 100 mass %, and still more preferably 80 mass % to 100 mass %, with respect to a total amount (100 mass %) of the inorganic filler (D) in the first resin composition layer, from the viewpoint of forming an interlayer insulating layer excellent in low thermal expansion, heat resistance, flame retardancy, and conductor adhesion.

### (Content of Inorganic Filler (D) in Second Resin Composition Layer)

A content of the inorganic filler (D) in the second resin composition layer is not particularly limited, and is preferably 1 mass % to 60 mass %, more preferably 2 mass % or more and less than 60 mass %, still more preferably 3 mass % to 55 mass %, even more preferably 4 mass % to 50 mass %, and particularly preferably 5 mass % to 40 mass %, from the viewpoint of forming an interlayer insulating layer excellent in low thermal expansion, heat resistance, and flame retardancy.

When the second resin composition layer contains silica, a content of the silica in the second resin composition layer is not particularly limited, and is preferably 1 mass % to 60 mass %, more preferably 2 mass % or more and less than 60 mass %, still more preferably 3 mass % to 55 mass %, even more preferably 4 to 50 mass %, and particularly preferably 5 mass % to 40 mass %, from the viewpoint of forming an interlayer insulating layer excellent in low thermal expansion, heat resistance, flame retardancy, and conductor adhesion.

When the second resin composition layer contains the component (D2), a content of the component (D2) in the second resin composition layer is not particularly limited, and is preferably 60 mass % to 100 mass %, more preferably 70 mass % to 100 mass %, and still more preferably 80 mass % to 100 mass %, with respect to a total amount (100 mass %) of the component (D) in the second resin composition layer, from the viewpoint of forming an interlayer insulating layer excellent in low thermal expansion, heat resistance, and flame retardancy.

### <(E) Fluorine-Containing Resin>

In the photosensitive multilayer resin film of the present embodiment, the second resin composition layer contains the fluorine-containing resin (E). Accordingly, the interlayer insulating layer formed of the photosensitive multilayer resin film of the present embodiment tends to have a reduced relative dielectric constant.

The fluorine-containing resin (E) may be used alone or may be used in combination of two or more types.

Examples of the fluorine-containing resin (E) include polymers of olefins containing fluorine atoms (hereinafter, also referred to as “fluorine-containing olefins”).

The fluorine-containing olefin may be an olefin in which some of hydrogen atoms in a carbon-hydrogen bond are substituted with fluorine atoms, and from the viewpoint of further reducing the relative dielectric constant, an olefin in which all hydrogen atoms in the carbon-hydrogen bond are substituted with fluorine atoms is preferable.

Examples of the fluorine-containing resin (E) include polymonofluoroethylene, polydifluoroethylene, polytrifluoroethylene, polytetrafluoroethylene, polyhexafluoropropylene, polyvinyl fluoride, and polyvinylidene fluoride. Among them, polytetrafluoroethylene is preferable.

The fluorine-containing resin (E) is preferably in the form of particles.

A volume-average particle diameter (D50) of the fluorine-containing resin (E) in the form of particles is not particularly limited, and is preferably 0.01 μm to 3.0 μm, more preferably 0.05 μm to 2.5 μm, and still more preferably 0.1 μm to 2.0 μm, from the viewpoint of the resolution.

### (Content of Component (E) in First Resin Composition Layer)

The first resin composition layer may contain the fluorine-containing resin (E), and preferably does not contain the fluorine-containing resin (E) from the viewpoint of the resolution and from the viewpoint of forming an interlayer insulating layer excellent in conductor adhesion.

When the first resin composition layer contains the fluorine-containing resin (E), a content of the fluorine-containing resin (E) in the first resin composition layer is preferably as small as possible, and is preferably 20 mass % or less, more preferably 10 mass % or less, and still more preferably 1 mass % or less, based on the total amount of the resin components in the first resin composition layer, from the same viewpoint as described above.

### (Content of Component (E) in Second Resin Composition Layer)

A content of the fluorine-containing resin (E) in the second resin composition layer is not particularly limited, and is preferably 10 mass % to 80 mass %, more preferably 15 mass % to 70 mass %, and still more preferably 20 mass % to 65 mass %, based on the total amount of the resin components in the second resin composition layer, from the viewpoint of the resolution, and from the viewpoint of forming an interlayer insulating layer excellent in insulation reliability, relative dielectric constant, heat resistance, and conductor adhesion.

### <(F) Elastomer>

The first resin composition layer and the second resin composition layer may each further contain the elastomer (F).

When the first resin composition layer and the second resin composition layer each contain the elastomer (F), the interlayer insulating layer to be formed tends to have further improved conductor adhesion.

The term “elastomer” as used herein means a polymer having a glass transition temperature of 25° C. or less as measured by differential scanning calorimetry in accordance with JIS K 6240:2011.

The elastomer (F) may be used alone or may be used in combination of two or more types.

Examples of the elastomer (F) include polybutadiene-based elastomers, polyester-based elastomers, styrene-based elastomers, olefin-based elastomers, urethane-based elastomers, polyamide-based elastomers, acrylic-based elastomers, silicone-based elastomers, and derivatives of these elastomers. Among them, polybutadiene-based elastomers are preferable from the viewpoint of compatibility with the resin components and from the viewpoint of forming an interlayer insulating layer excellent in conductor adhesion.

Suitable examples of the polybutadiene-based elastomer include those containing a 1,2-vinyl group derived from 1,3-butadiene.

From the viewpoint of the resolution, the polybutadiene-based elastomer is preferably a polybutadiene-based elastomer having an acid anhydride group, and more preferably a polybutadiene-based elastomer having an acid anhydride group derived from maleic anhydride.

When the polybutadiene-based elastomer has an acid anhydride group, the number of acid anhydride groups in one molecule is not particularly limited, and is preferably 1 to 12, more preferably 3 to 11, and still more preferably 6 to 10, from the viewpoint of the resolution and from the viewpoint of forming an interlayer insulating layer excellent in relative dielectric constant.

A number-average molecular weight (Mn) of the elastomer (F) is not particularly limited, and is preferably 1,000 to 100,000, more preferably 2,000 to 50,000, still more preferably 3,000 to 10,000, and particularly preferably 4,000 to 7,000.

In the present description herein, the number-average molecular weight (Mn) is a value determined by gel permeation chromatography (GPC) using tetrahydrofuran as a solvent in terms of standard polystyrene, and specifically a value measured according to a method described in Examples.

### (Content of Component (F) in First Resin Composition Layer)

When the first resin composition layer contains the elastomer (F), a content of the (F) elastomer in the first resin composition layer is not particularly limited, and is preferably 1 mass % to 30 mass %, more preferably 3 mass % to 20 mass %, and still more preferably 5 mass % to 15 mass %, based on the total amount of the resin components in the first resin composition layer, from the viewpoint of forming an interlayer insulating layer excellent in heat resistance and conductor adhesion.

### (Content of Component (F) in Second Resin Composition Layer)

When the second resin composition layer contains the elastomer (F), a content of the elastomer (F) in the second resin composition layer is not particularly limited, and is preferably 0.5 mass % to 20 mass %, more preferably 1 mass % to 15 mass %, and still more preferably 2 mass % to 10 mass %, based on the total amount of the resin components in the second resin composition layer, from the viewpoint of forming an interlayer insulating layer excellent in heat resistance and conductor adhesion.

### <(G) Organic Peroxide>

The first resin composition layer and the second resin composition layer preferably further each contain the organic peroxide (G). The organic peroxide (G) is a polymerization initiator for a thermal radical polymerization reaction of an ethylenically unsaturated group contained mainly in the component (A) and, if necessary, in the component (B).

When the first resin composition layer and the second resin composition layer each contain the organic peroxide (G), the interlayer insulating layer to be formed tends to have further improved heat resistance and dielectric characteristics.

The organic peroxide (G) may be used alone or may be used in combination of two or more types.

Examples of the organic peroxide (G) include peroxyketals such as 1,1-di(t-butylperoxy)cyclohexane, 2,2-di(t-butylperoxy) butane, 2,2-di(4,4-di-t-butylperoxycyclohexyl) propane, and 1,1-di(t-amylperoxy) cyclohexane; hydroperoxides such as cumene hydroperoxide and t-butyl hydroperoxide; alkyl peroxides such as t-butyl peroxyacetate and t-amyl peroxyisononanoate; dialkyl peroxides such as t-butylcumyl peroxide, di-t-butyl peroxide, peroxide, dicumyl di-t-hexyl peroxide, and 1,3-di(t-butylperoxyisopropyl)benzene; peroxy esters such as t-butyl peroxyacetate, t-butyl peroxybenzoate, and t-butylperoxyisopropyl monocarbonate; peroxy carbonates such as t-butylperoxyisopropyl carbonate and polyether tetrakis(t-butylperoxycarbonate); and diacyl peroxides such as dibenzoyl peroxide. Among them, 1,3-di(t-butylperoxyisopropyl)benzene is preferable.

### (Content of Component (G) in First Resin Composition Layer)

When the first resin composition layer contains the organic peroxide (G), a content of the organic peroxide (G) in the first resin composition layer is not particularly limited, and is preferably 0.1 parts by mass to 10 parts by mass, more preferably 1 part by mass to 7 parts by mass, and still more preferably 1.5 parts by mass to 4 parts by mass, with respect to 100 parts by mass of the component (A) in the first resin composition layer, from the viewpoint of forming an interlayer insulating layer excellent in heat resistance and conductor adhesion.

### (Content of Component (G) in Second Resin Composition Layer)

When the second resin composition layer contains the organic peroxide (G), a content of the organic peroxide (G) in the second resin composition layer is not particularly limited, and is preferably 0.1 parts by mass to 10 parts by mass, more preferably 1 part by mass to 7 parts by mass, and still more preferably 1.5 parts by mass to 4 parts by mass, with respect to 100 parts by mass of the component (A) in the second resin composition layer, from the viewpoint of forming an interlayer insulating layer excellent in heat resistance and conductor adhesion.

### <(H) Curing Accelerator>

Further, the first resin composition layer and the second resin composition layer preferably each contain the curing accelerator (H).

When the first resin composition layer and the second resin composition layer each contain the curing accelerator (H), the interlayer insulating layer to be formed tends to have further improved heat resistance and dielectric characteristics.

The curing accelerator (H) may be used alone or may be used in combination of two or more types.

Examples of the curing accelerator (H) include imidazole-based compounds such as 2-methylimidazole, 2-ethyl-4-methylimidazole, 1-benzyl-2-methylimidazole, 2-phenylimidazole, 2-phenyl-1-benzyl-1H-imidazole, 2-phenyl-4-methyl-5-hydroxymethylimidazole, and isocyanate-masked imidazole (addition reaction product of hexamethylene diisocyanate and 2-ethyl-4-methylimidazole); tertiary amines such as trimethylamine, N,N-dimethyloctylamine, N-benzyldimethylamine, pyridine, N-methylmorpholine, hexa (N-methyl) melamine, 2,4,6-tris(dimethylaminophenol), tetramethylguanidine, and m-aminophenol; organic phosphines such as tributylphosphine, triphenylphosphine, and tris-2-cyanoethylphosphine; phosphonium salts such as tri-n-butyl(2,5-dihydroxyphenyl)phosphonium bromide and hexadecyltributyl phosphonium chloride; quaternary ammonium salts such as benzyltrimethylammonium chloride and phenyltributylammonium chloride; the above-mentioned polybasic acid anhydrides; and diphenyliodonium tetrafluoroborate, triphenylsulfonium hexafluoroantimonate, and 2,4,6-triphenylthiopyrylium hexafluorophosphate.

Among them, imidazole-based compounds are preferable from the viewpoint of obtaining an excellent curing action.

### (Content of Component (H) in First Resin Composition Layer)

When the first resin composition layer contains the curing accelerator (H), a content of the curing accelerator (H) in the first resin composition layer is not particularly limited, and is preferably 0.1 parts by mass to 10 parts by mass, more preferably 0.5 parts by mass to 7 parts by mass, and still more preferably 1 part by mass to 4 parts by mass, with respect to 100 parts by mass of the component (B) in the first resin composition layer, from the viewpoint of forming an interlayer insulating layer excellent in heat resistance and conductor adhesion.

### (Content of Component (H) in Second Resin Composition Layer)

When the second resin composition layer contains the curing accelerator (H), a content of the curing accelerator (H) in the second resin composition layer is not particularly limited, and is preferably 0.1 parts by mass to 10 parts by mass, more preferably 0.5 parts by mass to 7 parts by mass, and still more preferably 1 part by mass to 4 parts by mass, with respect to 100 parts by mass of the component (B) in the second resin composition layer, from the viewpoint of forming an interlayer insulating layer excellent in heat resistance and conductor adhesion.

### <(I) Other Components>

The first resin composition layer and the second resin composition layer may each contain the components (I) other than the above components as necessary.

Examples of the other components (I) include resins other than the above-described components; an organic filler other than the component (E); a photosensitizer; a polymerization inhibitor; a foam stabilizer; a pigment; an adhesive aid such as melamine; a foam stabilizer such as a silicone compound; a thickener; and a flame retardant.

For each of these, one kind may be used alone, or two or more kinds may be used in combination.

A content of the other component (I) in the first resin composition layer or the second resin composition layer may be appropriately adjusted according to each purpose, and may be 0.01 mass % to 10 mass %, 0.05 mass % to 5 mass %, or 0.1 mass % to 1 mass % in the resin composition layer containing the component.

### <Method for Producing Photosensitive Multilayer Resin Film>

The photosensitive multilayer resin film of the present embodiment can be produced using a resin composition for forming the first resin composition layer (hereinafter, also referred to as “resin composition (1)”) and a resin composition for forming the second resin composition layer (hereinafter, also referred to as “resin composition (2)”).

The first resin composition layer can be formed of the resin composition (1), and a suitable content of each component in the total solid content of the resin composition (1) is the same as a suitable content of each component in the first resin composition layer. The second resin composition layer can be formed of the resin composition (2), and a suitable content of each component in the total solid content of the resin composition (2) is the same as a suitable content of each component in the second resin composition layer.

The resin composition (1) and the resin composition (2) can be produced by mixing components to be blended in each layer and a diluent to be used as necessary. For mixing the respective components, for example, a roll mill, a bead mill, a planetary mixer, or a self-revolving mixer can be used.

The first resin composition layer and the second resin composition layer are formed on separate carrier films using the resin composition (1) and the resin composition (2), and the two are then laminated together to produce the photosensitive multilayer resin film of the present embodiment having carrier films on both sides. As an alternative method, one of the resin composition layers may be formed on a carrier film, and the other resin composition layer may be formed by applying the other resin composition onto the first resin composition layer.

Examples of a method for applying the resin composition (1) and the resin composition (2) include a method using a coating device such as a comma coater, a bar coater, a kiss coater, a roll coater, a gravure coater, or a die coater.

A drying temperature when drying coatings of the resin composition (1) and the resin composition (2) is not particularly limited, and is preferably 60° C. to 150° C., more preferably 70° C. to 120° C., and still more preferably 80° C. to 100° C. A drying time is not particularly limited, and is preferably 1 minute to 60 minutes, more preferably 2 minutes to 30 minutes, and still more preferably 5 minutes to 20 minutes.

Examples of a material of the carrier film include polyesters such as polyethylene terephthalate and polybutylene terephthalate; and polyolefins such as polypropylene and polyethylene. A thickness of the carrier film is not particularly limited, and is preferably 5 μm to 100 μm, more preferably 10 μm to 60 μm, and still more preferably 15 μm to 45 μm.

### [Printed Wiring Board and Method for Producing Same]

The printed wiring board of the present embodiment is a printed wiring board having an interlayer insulating layer which is a cured product of the photosensitive multilayer resin film of the present embodiment.

Here, the term “interlayer insulating layer” in the printed wiring board of the present embodiment includes, for example, an interlayer insulating layer in a state after being subjected to various processes or treatments such as formation of a via and a wiring, and a roughening treatment.

The method for producing a printed wiring board of the present embodiment is not particularly limited as long as it is a method using the photosensitive multilayer resin film of the present embodiment, and a method for producing a printed wiring board including the following (1) to (4) is preferable.
(1): The photosensitive multilayer resin film of the present embodiment is laminated on one surface or both surfaces of a circuit board in a state where the second resin composition layer serves as an attachment surface (hereinafter, also referred to as “lamination step (1)”).
(2): The photosensitive multilayer resin film laminated in the above (1) is exposed and developed to form an interlayer insulating layer having a via (hereinafter, also referred to as “via forming step (2)”).
(3): The interlayer insulating layer having a via is heated and cured (hereinafter, also referred to as “heating and curing step (3)”).
(4): A circuit pattern is formed on a layer of the interlayer insulating layer formed by curing the first resin composition layer (hereinafter, also referred to as “circuit pattern forming step (4)”).

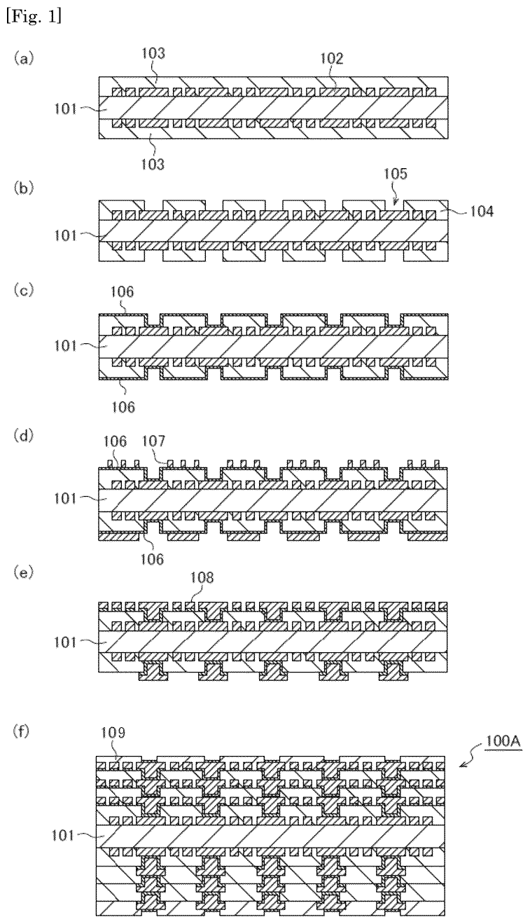

Hereinafter, the method for producing a printed wiring board of the present embodiment will be described with reference to FIG. 1 as appropriate.

In the present description herein, for the sake of convenience, a predetermined operation may be referred to as “XX step”, but the “XX step” is not limited to the embodiment specifically described in the present description herein.

### (Lamination Step (1))

In the lamination step (1), the photosensitive multilayer resin film of the present embodiment is laminated on one surface or both surfaces of a circuit board in a state where the second resin composition layer serves as an attachment surface.
(a) of FIG. 1 illustrates a process of forming a photosensitive layer 103 on both surfaces of a substrate 101 having a circuit pattern 102.

The photosensitive layer 103 can be formed by laminating the photosensitive multilayer resin film of the present embodiment on both surfaces of the substrate 101 such that the second resin composition layer serves as an attachment surface.

The lamination may be performed, for example, using a vacuum laminator while applying pressure and heat.

In a case where a carrier film is attached to the photosensitive layer 103 after the lamination, the carrier film may be peeled off before the exposure described later or may be peeled off after the exposure.

### (Via Forming Step (2))

In the via forming step (2), an interlayer insulating layer having a via is formed by exposing and developing the photosensitive layer formed in the lamination step (1).
(b) of FIG. 1 illustrates a process of forming an interlayer insulating layer 104 having a via 105 by exposing and developing the photosensitive layer 103.

By exposing the photosensitive layer 103, a photoradical polymerization reaction is initiated and the photosensitive multilayer resin film is cured.

The exposure method of the photosensitive layer 103 may be, for example, a mask exposure method of irradiating with an active ray in an image shape through a negative or positive mask pattern called artwork, or a method of irradiating with an active ray in an image shape by a direct drawing exposure method such as a laser direct imaging (LDI) exposure method or a digital light processing (DLP) exposure method.

Examples of the light source of the active ray include known light sources such as gas lasers such as a carbon arc lamp, a mercury vapor arc lamp, a high-pressure mercury lamp, a xenon lamp, and an argon laser; solid lasers such as a YAG laser; and semiconductor lasers which effectively emit ultraviolet light or visible light.

An exposure amount may be appropriately adjusted depending on the light source to be used, and the thickness of the photosensitive layer. For example, when a photosensitive layer having a thickness of 1 μm to 100 μm is exposed to ultraviolet radiation from a high-pressure mercury lamp, the exposure amount is not particularly limited, and is preferably 10 mJ/cm² to 1,000 mJ/cm², more preferably 50 mJ/cm² to 700 mJ/cm², and still more preferably 150 mJ/cm² to 400 mJ/cm².

Subsequently, when a carrier film is present on the photosensitive layer 103, the carrier film is removed, and then development is performed. In the development, an uncured portion of the photosensitive layer 103 is removed, and thus a photocured portion is formed on the substrate as the interlayer insulating layer 104.

The developing method may be wet development or dry development, and wet development is preferable. As the method by wet development, a spray system is preferable from the viewpoint of improving resolution.

Examples of the developing solution include an alkaline aqueous solution, a water-based developing solution, and an organic solvent-based developing solution, and among these, an alkaline aqueous solution is preferable.

After exposure and development, post-exposure may be performed from the viewpoint of increasing the degree of curing of the interlayer insulating layer. An exposure amount in the post-exposure is not particularly limited, and is preferably 0.2 J/cm² to 10 J/cm², and more preferably 0.5 J/cm² to 5 J/cm².

The shape of the via is not particularly limited, and examples of the cross-sectional shape include a quadrangular shape and an inverted trapezoidal shape. The inverted trapezoidal shape has an upper side longer than a lower side. The shape of the via in plan view includes a circular shape and a quadrangular shape.

In the formation of a via by the photolithography method of the present embodiment, a via having an inverted trapezoidal cross-sectional shape can be formed. The via having such a shape is preferable since plated copper has high throwing power to the wall surface of the via.

In the formation of the via by the photolithography method of the present embodiment, the diameter of the via can be made smaller than the diameter of the via formed by laser processing. The diameter of the via formed by the production method of the present embodiment may be, for example, 40 μm or less, may be 35 μm or less, or may be 30 μm or less. The lower limit value of the diameter of the via is not particularly limited, and may be, for example, 15 μm or more, or may be 20 μm or more.

### (Heating and Curing Step (3))

In the heating and curing step (3), the interlayer insulating layer having a via is heated and cured.

That is, in the heating and curing step (3), the curing reaction of the thermosetting component contained in the photosensitive multilayer resin film of the present embodiment is allowed to proceed by heating.

A heating temperature is not particularly limited, and is preferably 100° C. to 300° C., more preferably 120° C. to 200° C., and still more preferably 150° C. to 180° C. A heating time is not particularly limited, and is preferably 0.3 hours to 3 hours, more preferably 0.5 hours to 2 hours, and still more preferably 0.75 hours to 1.5 hours.

### (Circuit Pattern Forming Step (4))

Since the interlayer insulating layer formed as described above has a layer formed by curing the first resin composition layer exposed, in the circuit pattern forming step (4), a circuit pattern is formed on the layer of the interlayer insulating layer formed by curing the first resin composition layer.

The circuit pattern is preferably formed by a semi-additive process in which a roughening treatment, formation of a seed layer, formation of a resist pattern, formation of a copper circuit layer, and removal of the resist pattern are performed in this order from the viewpoint of forming fine wiring.

The roughening treatment is a treatment for roughening the surface of the interlayer insulating layer to form an uneven anchor. When a smear is generated in the via forming step (2), the roughening treatment and the removal of the smear may be simultaneously performed using a roughening solution. Examples of the roughening solution include an alkaline permanganate roughening solution such as a sodium permanganate roughening solution; a chromium/sulfuric acid roughening solution, and a sodium fluoride/chromium/sulfuric acid roughening solution.
(c) of FIG. 1 illustrates a process of forming a seed layer 106.

The seed layer 106 is for forming a power supply layer for performing electrolytic copper plating.

The seed layer 106 can be formed by performing an electroless copper plating treatment on the via bottom, the via wall surface, and the entire surface of the interlayer insulating layer using a palladium catalyst.
(d) of FIG. 1 illustrates a process of forming a resist pattern 107 on the seed layer 106.

The resist pattern 107 can be formed by, for example, thermocompression bonding a dry film resist on the seed layer 106 using a roll laminator, and exposing and developing the dry film resist. As the dry film resist, a commercially available product can be used.

The exposure of the dry film resist may be performed through a mask on which a desired wiring pattern is drawn. After the exposure, the dry film resist is developed using an alkaline aqueous solution to remove an unexposed portion, thereby forming a resist pattern 107. Thereafter, a plasma treatment for removing a development residue of the dry film resist may be performed as necessary.
(e) of FIG. 1 illustrates a process of forming a copper circuit layer 108.

The copper circuit layer 108 is preferably formed by electrolytic copper plating.

As the electrolytic copper plating solution used for electrolytic copper plating, for example, a commercially available electrolytic copper plating solution such as an electrolytic copper plating solution containing copper sulfate can be used.

After the electrolytic copper plating, the resist pattern 107 is removed by using an alkaline aqueous solution or an amine-based peeling agent, and flash etching for removing the seed layer 106 between the wirings, and removal of a palladium catalyst are appropriately performed by a known method. Further, if necessary, a post-baking treatment for sufficiently thermally curing the unreacted thermosetting component may be performed.
(f) of FIG. 1 illustrates a multilayer printed wiring board 100A which is multilayered by repeating the above processes and has a solder resist layer 109 on the outermost layer.

The solder resist layer 109 can be formed by using a known photosensitive multilayer resin film for solder resist.

The method for producing a printed wiring board in which a via is formed using the photosensitive multilayer resin film of the present embodiment has been described above. Since the photosensitive multilayer resin film of the present embodiment has excellent pattern resolution, the photosensitive multilayer resin film of the present embodiment is also suitable for forming, for example, a cavity for embedding a chip or a passive element. The cavity can be suitably formed, for example, by using a drawing pattern capable of forming a desired cavity when the photosensitive multilayer resin film is exposed to form a pattern in the description of the printed wiring board described above.

### [Semiconductor Package]

The semiconductor package of the present embodiment is a semiconductor package including the printed wiring board of the present embodiment.

The semiconductor package of the present embodiment can be produced, for example, by mounting a semiconductor element such as a semiconductor chip or a memory on a predetermined position of the printed wiring board of the present embodiment and sealing the semiconductor element with a sealing resin.

### EXAMPLE

Hereinafter, the present embodiment will be described in more detail with reference to Examples, but the present embodiment is not limited to these Examples.

### [Measurement Method of Acid Value]

The acid value was calculated from the amount of a potassium hydroxide aqueous solution required to neutralize a measurement target.

### [Measurement Method of Weight-Average Molecular Weight (Mw) and Number-Average Molecular Weight (Mn)]

The weight-average molecular weight (Mw) and the number-average molecular weight (Mn) were measured with the following GPC measurement apparatus under the following measurement conditions, and were determined by conversion using a calibration curve of standard polystyrene. For the preparation of the calibration curve, 5 sample sets (“PStQuick MP-H” and “PStQuick B”, manufactured by Tosoh Corporation) were used as the standard polystyrene.

### (GPC Measurement Apparatus)

GPC apparatus: high-speed GPC apparatus “HCL-8320GPC”, detector is differential refractometer or UV, manufactured by Tosoh Corporation
Column: column TSKgel SuperMultipore HZ-H (column length: 15 cm, column inner diameter: 4.6 mm), manufactured by Tosoh Corporation

### (Measurement Conditions)

Solvent: tetrahydrofuran (THF)
Measurement temperature: 40° C.
Flow rate: 0.35 mL/min
Sample concentration: 10 mg/5 mL of THF
Injection volume: 20 μL

### [Measurement Method of Fluorine Atom Concentration]

The photosensitive multilayer resin film with a carrier film produced in each Example was irradiated with ultraviolet light at a light intensity of 400 mJ/cm² (wavelength 365 nm) using a flat exposure machine while the carrier films were still attached to both sides. Thereafter, the carrier films on both sides were peeled off and removed, and the photosensitive multilayer resin film was irradiated with ultraviolet light at a light intensity of 2 J/cm² (wavelength 365 nm) using a UV conveyor-type exposure machine. The photosensitive multilayer resin film was then heated at 170° C. for 1 hour using a hot air circulating dryer to obtain a cured product of the photosensitive multilayer resin film. The cured product of the photosensitive multilayer resin film thus obtained was embedded in an embedding resin, cured, and then polished using a polishing machine (trade name “Refine Polisher”, manufactured by Refine Tec Ltd.) to obtain a cross section of the cured product of the photosensitive multilayer resin film, which was then used as a test piece.

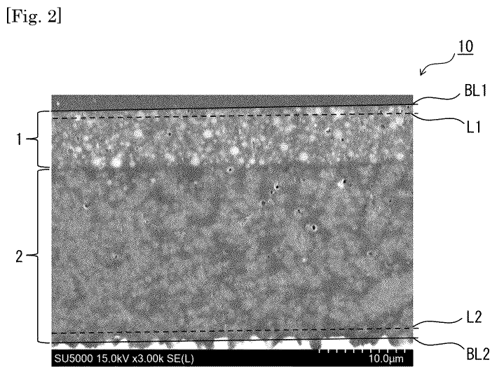

Next, the cross section of the cured product of the photosensitive multilayer resin film was observed at 3,000× magnification using a scanning electron microscope (SEM) (trade name “SU-5000”, manufactured by Hitachi High-Tech Corporation) equipped with an energy dispersive X-ray spectroscopy (EDX) as an elemental analysis apparatus. FIG. 2 shows an example of a cross-sectional image 10 of the cured product of the photosensitive multilayer resin film. The cured product includes a layer 1 formed by curing the first resin composition layer (hereinafter, also referred to as “first layer 1”) and a layer 2 formed by curing the second resin composition layer (hereinafter, also referred to as “second layer 2”). Hereinafter, a measurement position for the fluorine atom concentration will be described with reference to FIG. 2.

In the cross-sectional image 10 shown in FIG. 2, a line corresponding to the surface of the first layer 1 opposite to the surface facing the second layer 2 was specified as a reference line BL1 of the first layer. The surface of the second layer 2 opposite to the surface facing the first layer 1 was specified as a reference line BL2 of the second layer.

In the case where unevenness is present on the surfaces of the first layer and the second layer that specify the reference line BL1 and the reference line BL2, a straight line obtained by plotting at least 10 surface positions on the respective layers at equal intervals over the entire range of the cross-sectional image and approximating the 10 surface positions by a least squares method can be used as the reference line BL1 or the reference line BL2.

On a measurement line L1 which is 1 μm away from the reference line BL1 toward the second layer 2 side and is parallel to the reference line BL1, elemental analysis of the first layer 1 was performed using the above-described elemental analysis apparatus, and the calculated average fluorine atom concentration was defined as “fluorine atom concentration in the first layer”. On a measurement line L2 which is 1 μm away from the reference line BL2 toward the first layer 1 side and is parallel to the reference line BL2, elemental analysis of the second layer 2 was performed using the above-described elemental analysis apparatus, and the calculated average fluorine atom concentration was defined as “fluorine atom concentration in the second layer”. A line length for performing elemental analysis was 40 μm.

A ratio of the fluorine atom concentration in the first layer to the fluorine atom concentration in the second layer obtained above was calculated as a fluorine atom concentration ratio [(first layer)/(second layer)].

### [Production of Photosensitive Multilayer Resin Film]

### Examples 1 to 6 and Comparative Examples 1 to 3

Each component was blended according to the blending composition shown in Table 1 (the unit of the numerical value in the table is a part by mass, and in the case of a solution, it is an amount converted into a solid content) and kneaded using a three roll mill and a self-revolving mixer. Thereafter, methyl ethyl ketone was added such that the solid content concentration was 65 mass %, thereby obtaining the resin composition (1) for forming the first resin composition layer and the resin composition (2) for forming the second resin composition layer.

Next, the resin composition (1) was applied onto a carrier film (PET film, manufactured by Teijin Limited., trade name “G2-16”, thickness: 16 μm), and dried at 100° C. for 10 minutes using a hot air convection dryer to form the first resin composition layer with a carrier film (thickness of the first resin composition layer: 5 μm).

The resin composition (2) was applied onto a carrier film (PET film, manufactured by Teijin Limited., trade name “G2-16”, thickness: 16 μm) different from the above, and dried at 100° C. for 10 minutes using a hot air convection dryer to form the second resin composition layer with a carrier film (thickness of the second resin composition layer: 20 μm).

The resin composition layers of the first resin composition layer with a carrier film and the second resin composition layer with a carrier film obtained above were bonded to each other to obtain a photosensitive multilayer resin film with a carrier film including the carrier film, the first resin composition layer, the second resin composition layer, and the carrier film in this order (the thickness of the photosensitive multilayer resin film: 25 μm).

The prepared photosensitive multilayer resin film was subjected to the following evaluations. The results are shown in Table 1.

### [Measurement of Relative Dielectric Constant (Dk) and Dielectric Dissipation Factor (Df)]

Two sheets of the photosensitive multilayer resin film with a carrier film produced in each Example, from which the carrier film on the second resin composition layer side was peeled and removed, were prepared, and the second resin composition layers were bonded to each other.

Next, while the carrier films on both sides were still attached, the photosensitive multilayer resin film was irradiated with ultraviolet light at a light intensity of 400 mJ/cm² (wavelength 365 nm) using a flatbed exposure machine. Next, the carrier films on both sides were peeled off and removed, and the photosensitive multilayer resin film was irradiated with ultraviolet light at a light intensity of 2 J/cm² (wavelength 365 nm) using a UV conveyor-type exposure machine. Thereafter, the photosensitive multilayer resin film was heated at 170° C. for 1 hour using a hot air circulating dryer and cut into a size of 7 cm×10 cm to obtain a measurement sample for a relative dielectric constant (Dk) and a dielectric dissipation factor (Df).

The measurement sample obtained above was dried at 105° C. for 10 minutes using a hot air circulating dryer, and then the relative dielectric constant (Dk) and the dielectric dissipation factor (Df) were measured in a 10 GHz band using a split post dielectric resonator method (SRDR method), and evaluated according to the following criteria.

### (Evaluation Criterion of Relative Dielectric Constant (Dk))

A: 2.8 or less
B: more than 2.8 to 3.0 or less
C: more than 3.0

### (Evaluation Criterion of Dielectric Dissipation Factor (Df))

A: 0.0100 or less
B: more than 0.0100 to 0.0120 or less
C: more than 0.0120

### [Evaluation of Resolution of Via]

### (1) Preparation of Laminated Body for Evaluation

A copper foil surface of a printed wiring board substrate (trade name “MCL-E-679”, manufactured by Showa Denko Materials co., Ltd.) obtained by laminating a copper foil (thickness: 12 μm) on a glass epoxy substrate was subjected to a pre-roughening treatment with a pre-roughening treatment solution (trade name “CZ-8100”, manufactured by MEC Company Ltd.), and then washed with water and dried. Next, the carrier film of the photosensitive multilayer resin film with a carrier film produced in each Example on the second resin composition layer side was peeled off and removed, and the exposed second resin composition layer was laminated onto a copper foil of the pre-roughened printed wiring board substrate such that the second resin composition layer serves as an attachment surface. For the laminating, a press-type vacuum laminator (manufactured by The Japan Steel Works, Ltd., Meiki Plant, trade name “MVLP-500”) was used, and the laminating conditions were a press hot plate temperature of 70° C., a vacuuming time of 20 seconds, a laminating press time of 30 seconds, a pressure of 4 kPa or less, and a compression pressure of 0.4 MPa. After the lamination treatment, the laminated body was allowed to stand at room temperature for 1 hour or more to obtain a laminated body for evaluation in which the photosensitive multilayer resin film and the carrier film were laminated in this order on the copper foil surface of the printed wiring board substrate.

### (2) Sensitivity Measurement

A 41-step tablet was disposed on the carrier film of the laminated body for evaluation obtained above on the first resin composition layer side. Next, exposure was performed using a direct imaging exposure apparatus (trade name “DXP-3512”, manufactured by ORC Manufacturing Co., Ltd.) using an ultrahigh pressure mercury lamp as a light source. The exposure pattern used was a dot pattern in which dots ranging from φ30 μm to φ100 μm were arranged in a lattice pattern.

After the exposure, the laminated body for evaluation was allowed to stand at room temperature for 30 minutes, then the carrier film of the laminated body for evaluation obtained above on the first resin composition layer side was removed, and an unexposed portion of the photosensitive multilayer resin film was subjected to spray development with a 1 mass % sodium carbonate aqueous solution at 30° C. for 60 seconds. After the development, the exposure energy amount at which the gloss remaining step number of the 41-step tablet was 4.0 was determined as the sensitivity (unit: mJ/cm²) of the photosensitive multilayer resin film. The pattern exposed with the sensitivity was evaluated according to the following evaluation criteria.

### (3) Evaluation of Resolution of Via

The resolution of the via was evaluated according to the following criteria by observing, using an optical microscope, the via pattern formed by exposure and spray development with the exposure energy amount which is the sensitivity of the photosensitive multilayer resin film determined in the above (2).

### (Evaluation Criteria)

A: The φ60 μm via portion of the dot pattern is opened.
C: The φ60 μm via portion of the dot pattern is not opened.
   [Evaluation of Adhesive Strength with Plated Copper]

### (1) Preparation of Laminated Body for Evaluation and Sensitivity Measurement of Photosensitive Multilayer Resin Film

In the procedures of (1) and (2) in the above [Evaluation of Resolution of Via], except for changing the used exposure machine to a parallel light exposure machine (trade name “EXM-1201”, manufactured by ORC Manufacturing Co., Ltd.) using an ultrahigh pressure mercury lamp as a light source, operations same as those in (1) and (2) in the above [Evaluation of Resolution of Via] were performed to prepare a laminated body for evaluation, and the exposure energy amount at which the gloss remaining step number was 8.0 was determined, and this was taken as the sensitivity (unit: mJ/cm²) of the photosensitive multilayer resin film.

### (2) Exposure Step and Development Step

The carrier film of the laminated body for evaluation on the first resin composition layer side was peeled off and removed, and the laminated body for evaluation was subjected to whole surface exposure with the exposure energy amount as the sensitivity obtained above to cure the photosensitive multilayer resin film. After the exposure, the photosensitive multilayer resin film was allowed to stand at room temperature for 30 minutes, and then an unexposed portion of the photosensitive multilayer resin film was subjected to spray development with a 1 mass % sodium carbonate aqueous solution at 30° C. for 60 seconds.

### (3) Post-Cure Treatment

Subsequently, post-UV curing was performed at a conveyor speed at which the exposure amount was 2 J/cm² using a UV conveyor apparatus of a high-pressure mercury lamp irradiation type (manufactured by ORC Manufacturing Co., Ltd.). Thereafter, the photosensitive multilayer resin film was heated at 170° C. for 1 hour using a hot air circulating dryer.

### (4) Roughening Treatment

The heated laminated body for evaluation was treated at 70° C. for 5 minutes using a swelling solution “Swelling Dip SECURIGANTH P”, and then subjected to a roughening treatment at 70° C. for 10 minutes using a roughening solution “Dosing SECURIGANTH P500J”. Subsequently, a neutralization treatment was performed at 50° C. for 5 minutes using a neutralizing solution “Reduction Conditioner SECURIGANTH P500”. Thereafter, a hydrofluoric acid treatment was performed at room temperature for 10 minutes using buffered hydrofluoric acid “LAL1800 SA Ultra High Purity Buffered Hydrogen Fluoride”. Note that the swelling solution, the roughening solution, and the neutralizing solution were all manufactured by Atotech Japan K.K., and the buffered hydrofluoric acid was manufactured by Stella Chemifa Corporation.

### (5) Plating Treatment

The laminated body for evaluation after the roughening treatment was subjected to an electroless plating treatment at 30° C. for 15 minutes using an electroless plating solution “Print Gantt MSK-DK” (manufactured by Atotech Japan K.K.). Next, an electroplating treatment was performed at 24° C. and 2 A/dm² for 1.5 hours using an electroplating solution “Cupracid HL” (manufactured by Atotech Japan K.K.) to form plated copper on the interlayer insulating layer. The thickness of the plated copper was set to 25 μm.

(6) Measurement of Adhesive Strength with Plated Copper

The adhesive strength with plated copper was measured by measuring the vertical peel strength at 23° C. in accordance with JIS C6481: 1996, and evaluated according to the following criteria.

### (Evaluation Criteria)

A: more than 0.4 kN/m
B: more than 0.1 kN/m and 0.4 kN/m or less
C: 0.1 kN/m or less

TABLE 1

| | | | | Example | | | |
|---|---|---|---|---|---|---|---|
| | | | | 1 | 2 | 3 | 4 |
| Blending | First | Component (A) | Compound having carboxy group | 100 | 100 | 100 | 100 |
| composition | resin | | and acryloyl group | | | | |
| (parts | composition | | Dipentaerythritol hexaacrylate | 28 | 28 | 28 | 24 |
| by | layer | | Trimethylolpropane triacrylate | | | | |
| mass) | | Component (B) | Biphenyl aralkyl type epoxy resin | 56 | 56 | 56 | 78 |
| of | | | Naphthol type epoxy resin | 84 | 84 | 84 | 117 |
| each | | | Hexamethylene diisocyanate | 27 | 27 | 27 | 27 |
| resin | | | Maleimide resin | | | | |
| composition | | Component (C) | Photopolymerization initiator 1 | 0.5 | 0.5 | 0.5 | 0.5 |
| layer | | | Photopolymerization initiator 2 | 0.1 | 0.1 | 0.1 | 0.1 |
| | | Component (D) | Silica 1 | 224 | 224 | 224 | 224 |
| | | | Silica 2 | | | | |
| | | Component (E) | Polytetrafluoroethylene particles | | | | |
| | | Component (F) | Polybutadiene-based elastomer | 10 | 10 | 10 | 10 |
| | | | Acid anhydride modified | 22 | 22 | 22 | 22 |
| | | | polybutadiene | | | | |
| | | Component (G) | Organic peroxide | 3.5 | 3.5 | 3.5 | 3.5 |
| | | Component (H) | Curing accelerator | 3.0 | 3.0 | 3.0 | 3.0 |
| | | Component (I) | Sensitizer | 2.0 | 2.0 | 2.0 | 2.0 |
| | | | Polymerization inhibitor | 1.5 | 1.5 | 1.5 | 1.5 |
| | Second | Component (A) | Compound having carboxy group | 100 | 100 | 100 | 100 |
| | resin | | and acryloyl group | | | | |
| | composition | | Dipentaerythritol hexaacrylate | | | | |
| | layer | | Trimethylolpropane triacrylate | 70 | 63 | 63 | 70 |
| | | Component (B) | Biphenyl aralkyl type epoxy resin | 18 | 18 | 18 | 18 |
| | | | Naphthol type epoxy resin | 28 | 28 | 28 | 28 |
| | | | Hexamethylene diisocyanate | 26 | | | 26 |
| | | | Maleimide resin | 46 | 46 | 46 | 46 |
| | | Component (C) | Photopolymerization initiator 1 | 0.5 | 0.5 | 0.5 | 0.5 |
| | | | Photopolymerization initiator 2 | 0.1 | 0.1 | 0.1 | 0.1 |
| | | Component (D) | Silica 1 | | 110 | 159 | |
| | | | Silica 2 | 33 | | | 33 |
| | | Component (E) | Polytetrafluoroethylene particles | 163 | 433 | 83 | 163 |
| | | Component (F) | Polybutadiene-based elastomer | 8 | 8 | 8 | 8 |
| | | | Acid anhydride modified | 25 | 22 | 22 | 25 |
| | | | polybutadiene | | | | |
| | | Component (G) | Organic peroxide | 3.5 | 3.5 | 3.5 | 3.5 |
| | | Component (H) | Curing accelerator | 3.0 | 3.0 | 3.0 | 3.0 |
| | | Component (I) | Sensitizer | 2.0 | 2.0 | 2.0 | 2.0 |
| | | | Polymerization inhibitor | 1.5 | 1.5 | 1.5 | 1.5 |
| Fluorine | Fluorine atom concentration (mass %) in first layer | | | 0 | 0 | 0 | 0 |
| atom | Fluorine atom concentration (mass %) in second layer | | | 20 | 53 | 10 | 20 |
| concen- | | | | | | | |
| tration | | | | | | | |

| | | | | | | |
|---|---|---|---|---|---|---|
| Evaluation | Dielectric | Relative dielectric constant (Dk) | A | A | A | A |
| results | characteristics | Dielectric dissipation factor (Df) | A | A | A | A |

| | | | | |
|---|---|---|---|---|
| Resolution of Via | A | A | A | A |
| Adhesive strength with plated copper | A | A | A | A |

| | | | | | | Comparative | | |
|---|---|---|---|---|---|---|---|---|
| | | | | Example | | Example | | |
| | | | | 5 | 6 | 1 | 2 | 3 |
| Blending | First | Component (A) | Compound having carboxy group | 100 | 100 | 100 | 100 | 100 |
| composition | resin | | and acryloyl group | | | | | |
| (parts | composition | | Dipentaerythritol hexaacrylate | 28 | 103 | 28 | | |
| by | layer | | Trimethylolpropane triacrylate | | | | 70 | 70 |
| mass) | | Component (B) | Biphenyl aralkyl type epoxy resin | 56 | 18 | 56 | 18 | 37 |
| of | | | Naphthol type epoxy resin | 84 | 28 | 84 | 28 | 55 |
| each | | | Hexamethylene diisocyanate | 27 | | 27 | 26 | 26 |
| resin | | | Maleimide resin | | 47 | | 46 | |
| composition | | Component (C) | Photopolymerization initiator 1 | 0.5 | 0.5 | 0.5 | 0.5 | 0.5 |
| layer | | | Photopolymerization initiator 2 | 0.1 | 0.1 | 0.1 | 0.1 | 0.1 |
| | | Component (D) | Silica 1 | 224 | 228 | 224 | | |
| | | | Silica 2 | | | | 33 | 33 |
| | | Component (E) | Polytetrafluoroethylene particles | | | | 163 | 163 |
| | | Component (F) | Polybutadiene-based elastomer | 10 | 8 | 10 | 8 | 8 |
| | | | Acid anhydride modified | 22 | 22 | 22 | 25 | 25 |
| | | | polybutadiene | | | | | |
| | | Component (G) | Organic peroxide | 3.5 | 3.5 | 3.5 | 3.5 | 3.5 |
| | | Component (H) | Curing accelerator | 3.0 | 3.0 | 3.0 | 3.0 | 3.0 |
| | | Component (I) | Sensitizer | 2.0 | 2.0 | 2.0 | 2.0 | 2.0 |
| | | | Polymerization inhibitor | 1.5 | 1.5 | 1.5 | 1.5 | 1.5 |
| | Second | Component (A) | Compound having carboxy group | 100 | 100 | 100 | 100 | 100 |
| | resin | | and acryloyl group | | | | | |
| | composition | | Dipentaerythritol hexaacrylate | | | 28 | | |
| | layer | | Trimethylolpropane triacrylate | 62 | 70 | | 70 | 70 |
| | | Component (B) | Biphenyl aralkyl type epoxy resin | 18 | 18 | 56 | 18 | 37 |
| | | | Naphthol type epoxy resin | 28 | 28 | 84 | 28 | 55 |
| | | | Hexamethylene diisocyanate | | 26 | 27 | 26 | 26 |
| | | | Maleimide resin | 46 | 46 | | 46 | |
| | | Component (C) | Photopolymerization initiator 1 | 0.5 | 0.5 | 0.5 | 0.5 | 0.5 |
| | | | Photopolymerization initiator 2 | 0.1 | 0.1 | 0.1 | 0.1 | 0.1 |
| | | Component (D) | Silica 1 | 157 | | 224 | | |
| | | | Silica 2 | | 33 | | 33 | 33 |
| | | Component (E) | Polytetrafluoroethylene particles | 77 | 163 | | 163 | 163 |
| | | Component (F) | Polybutadiene-based elastomer | 8 | 8 | 10 | 8 | 8 |
| | | | Acid anhydride modified | 22 | 25 | 22 | 25 | 25 |
| | | | polybutadiene | | | | | |
| | | Component (G) | Organic peroxide | 3.5 | 3.5 | 3.5 | 3.5 | 3.5 |
| | | Component (H) | Curing accelerator | 3.0 | 3.0 | 3.0 | 3.0 | 3.0 |
| | | Component (I) | Sensitizer | 2.0 | 2.0 | 2.0 | 2.0 | 2.0 |
| | | | Polymerization inhibitor | 1.5 | 1.5 | 1.5 | 1.5 | 1.5 |
| Fluorine | Fluorine atom concentration (mass %) in first layer | | | 0 | 0 | 0 | 20 | 20 |
| atom | Fluorine atom concentration (mass %) in second layer | | | 9 | 20 | 0 | 20 | 20 |
| concen- | | | | | | | | |
| tration | | | | | | | | |

| | | | | | | | |
|---|---|---|---|---|---|---|---|
| Evaluation | Dielectric | Relative dielectric constant (Dk) | B | A | C | A | A |
| results | characteristics | Dielectric dissipation factor (Df) | A | A | C | A | A |

| | | | | | |
|---|---|---|---|---|---|
| Resolution of Via | A | A | C | A | A |
| Adhesive strength with plated copper | A | B | A | C | C |

The details of each component shown in Table 1 are as follows.

### [Component (A)]

Compound having a carboxy group and an acryloyl group: manufactured by Nippon Kayaku Co., Ltd., trade name “ZXR-1807H”, acid value: 110 mgKOH/g, weight-average molecular weight (Mw): 2,000

### [Component (B)]

Biphenyl aralkyl type epoxy resin: manufactured by Nippon Kayaku Co., Ltd., trade name “NC-3000-L”, epoxy group equivalent: 272 g/eq
Naphol-type epoxy resin: manufactured by Nippon Steel & Sumikin Co., Ltd., trade name “ESN-475V”, epoxy group equivalent: 325 g/eq
Maleimide resin: aromatic bismaleimide resin having an indane skeleton

### [Component (C)]

Photopolymerization initiator 1: phenylbis(2,4,6-trimethylbenzoyl) phosphine oxide
Photopolymerization initiator 2: 1-[9-ethyl-6-(2-methylbenzoyl)-9H-carbazol-3-yl]ethanone 1-(O-acetyloxime)

### [Component (D)]

Silica 1: manufactured by Admatechs Co., Ltd., trade name “SC2050-MB”, average particle diameter (D₅₀): 0.5 μm, true density: 2,200 kg/m³
Silica 2: manufactured by TAT, trade name “BQQ-0710SCB”, average particle diameter (D₅₀): 0.7 μm, true density: 1,350 kg/m³

### [Component (E)]

Polytetrafluoroethylene particles: manufactured by Mitsubishi Pencil Co., Ltd., trade name “MPT-N8”, average particle diameter (D₅₀): 0.2 μm to 0.3 μm

### [Component (F)]

Polybutadiene-based elastomer: butadiene-styrene random copolymer, manufactured by Cray Valley, trade name “Ricon100”, number-average molecular weight (Mn): 4,500
Acid anhydride modified polybutadiene: manufactured by Cray Valley, trade name “Ricon131MA17”, number-average molecular weight (Mn): 5,400, number of acid anhydride groups in one molecule: 9

### [Component (G)]

Organic peroxide: 1,3-di(t-butylperoxyisopropyl)benzene

### [Component (H)]

Curing accelerator: 1-benzyl-2-phenylimidazole

### [Component (I)]

Sensitizer: 4,4′-bis-(diethylamino)benzophenone
Polymerization inhibitor: 4-tert-butylpyrocatechol

From Table 1, all the cured products formed from the photosensitive multilayer resin films in Examples 1 to 6 of the present embodiment had excellent dielectric characteristics and high conductor adhesion.

### REFERENCE SIGNS LIST

1: First Layer
2: Second Layer
BL1: Reference line of first layer
BL2: Reference line of second layer
L1: Measurement line of first layer
L2: Measurement line of second layer
10: Cross-sectional image
100A: Multilayer printed wiring board
101: Substrate
102: Circuit pattern
103: Photosensitive layer
104: Interlayer insulating layer
105: Via
106: Seed Layer
107: Resist pattern
108: Copper circuit layer
109: Solder resist layer

1. A photosensitive multilayer resin film comprising:
a first resin composition layer; and
a second resin composition layer, wherein
the first resin composition layer and the second resin composition layer each contain a compound (A) having an ethylenically unsaturated group, a thermosetting resin (B), a photopolymerization initiator (C), and an inorganic filler (D),
the second resin composition layer further contains a fluorine-containing resin (E), and
a fluorine atom concentration in the first resin composition layer is lower than a fluorine atom concentration in the second resin composition layer.

2. The photosensitive multilayer resin film according to claim 1, wherein the first resin composition layer and the second resin composition layer each contain, as the compound (A) having an ethylenically unsaturated group, a compound having an ethylenically unsaturated group and an acidic substituent.

3. The photosensitive multilayer resin film according to claim 1, wherein the first resin composition layer and the second resin composition layer each contain, as the thermosetting resin (B), one or more selected from the group consisting of an epoxy resin, a maleimide resin, an allyl resin, and a vinyl resin.

4. The photosensitive multilayer resin film according to claim 3, wherein the first resin composition layer and the second resin composition layer each contain an epoxy resin as the thermosetting resin (B), and a content of the epoxy resin in the first resin composition layer on a mass basis is greater than a content of the epoxy resin in the second resin composition layer on a mass basis.

5. The photosensitive multilayer resin film according to claim 1, wherein the first resin composition layer contains silica as the inorganic filler (D), and a content of the silica in the first resin composition layer is 5 mass % to 70 mass %.

6. The photosensitive multilayer resin film according to claim 1, wherein the second resin composition layer contains silica having a true density of 1,500 kg/m³ or less as the inorganic filler (D).

7. The photosensitive multilayer resin film according to claim 1, wherein a content of the fluorine-containing resin (E) in the second resin composition layer is 10 mass % to 80 mass % based on a total amount of resin components in the second resin composition layer.

8. The photosensitive multilayer resin film according to claim 1, wherein the first resin composition layer and the second resin composition layer each further contain an elastomer (F).

9. The photosensitive multilayer resin film according to claim 1, wherein a layer formed by curing the first resin composition layer is a layer on which a circuit pattern is to be formed by copper plating, and the second resin composition layer is a layer having a surface to be attached when laminating the photosensitive multilayer resin film.

10. The photosensitive multilayer resin film according to claim 1, which is used for forming an interlayer insulating layer having a photovia.

11. A printed wiring board comprising:
an interlayer insulating layer which is a cured product of the photosensitive multilayer resin film according to claim 1.

12. A semiconductor package comprising:
the printed wiring board according to claim 11.

13. A method for producing a printed wiring board, comprising:
the following (1) to (4):
(1): laminating the photosensitive multilayer resin film according to claim 1 on one surface or both surfaces of a circuit board in a state where the second resin composition layer serves as an attachment surface;
(2): forming an interlayer insulating layer having a via by exposing and developing the photosensitive multilayer resin film laminated in the (1);
(3): heating and curing the interlayer insulating layer having a via; and
(4): forming a circuit pattern on a layer of the interlayer insulating layer formed by curing the first resin composition layer.
